(19) United States
(12) Patent Application Publication
(10) Pub. No.: US 2026/0324209 A1
(43) Pub. Date: Oct. 15, 2026

(54) DISPLAY DEVICE, METHOD OF MANUFACTURING THE DISPLAY DEVICE AND ELECTRONIC DEVICE INCLUDING THE DISPLAY DEVICE

(71) Applicant: Samsung Display Co., Ltd., Yongin-si (KR)

(72) Inventors: HOKIL OH, Yongin-si (KR); DOHYUN KWON, Yongin-si (KR); KYUNGMIN PARK, Yongin-si (KR); JINSUK PARK, Yongin-si (KR); KYEONGYE SEO, Yongin-si (KR); Yeji Shin, Yongin-si (KR); KWANGSIK LEE, Yongin-si (KR); SOHYEON LEE, Yongin-si (KR); Jongheon Lee, Yongin-si (KR)

(21) Appl. No.: 19/646,403

(22) Filed: Apr. 13, 2026

(30) Foreign Application Priority Data
Apr. 14, 2025 (KR) 10-2025-0048163

(51) Int. Cl. H10K 59/123; H10K 59/12; H10K 59/131; H10K 102/00

(52) U.S. Cl. CPC H10K 59/123; H10K 59/1201; H10K 59/131; H10K 2102/351

(57) ABSTRACT

A method of manufacturing a display device includes applying an active layer on a portion of a base substrate in a display area, the base substrate defining the display area and a pad area, applying a gate electrode overlapping the active layer in a display area and a bottom pad in a pad area, applying a contact electrode connected to the active layer in the display area and a first pad connected to the bottom pad in the pad area, applying a via insulation layer covering the contact electrode, applying a via electrode connected to the contact electrode through the via insulation layer and a second pad connected to the first pad, partially etching an upper portion of the first pad or the second pad while etching the via insulation layer in the pad area, and applying a light-emitting element electrically connected to the via electrode.

### CROSS-REFERENCE TO RELATED APPLICATION

The present application claims priority to and the benefit of Korean Patent Application No. 10-2025-0048163, filed on Apr. 14, 2025, in the Korean Intellectual Property Office, the entire disclosure of which is incorporated herein by reference.

### BACKGROUND

### 1. Field

Embodiments of the present disclosure relate to a display device, a method of manufacturing the display device, and an electronic device including the display device. For example, embodiments of the present disclosure relate to a display device including connection electrodes and pad, a method of manufacturing the display device, and an electronic device including the display device.

### 2. Description Of The Related Art

A display device, such as an organic light-emitting diode (OLED) display device and/or a liquid crystal display (LCD) device, may include a display substrate including a thin film transistor (TFT) and one or more suitable wirings. A display structure including electrodes and an emission layer may be formed on the display substrate.

The electrodes may include wiring and contact electrodes that electrically connect a transistor structure to the display structure. In addition, the electrodes may include pads for applying a signal to the display structure.

When forming the pads, an additional etching process may be performed, which may cause physical and/or chemical damage to the pads.

The above information disclosed in this Background section is intended to enhance understanding of the background of the disclosure and may contain information that does not constitute prior art.

### SUMMARY

Aspects of one or more embodiments of the present disclosure are directed to a display device having improved electrical characteristics and structural reliability.

Aspects of one or more embodiments of the present disclosure are directed to a method of manufacturing the display device having improved electrical characteristics and structural reliability.

Aspects of one or more embodiments of the present disclosure are directed to an electronic device including the display device having improved electrical characteristics and structural reliability.

Additional aspects will be set forth in part in the description which follows and, in part, will be apparent from the description, or may be learned by practice of the presented embodiments of the disclosure.

According to one or more embodiments of the present disclosure, a method of manufacturing a display device includes forming (e.g., applying) an active layer on a portion of a base substrate in a display area, wherein the base substrate includes (e.g., defines) the display area and a pad area, forming (e.g., applying) a gate electrode overlapping the active layer in the display area and a bottom pad on a portion of the base substrate in the pad area, forming (e.g., applying) a contact electrode connected to the active layer in the display area and a first pad connected to the bottom pad in the pad area, forming (e.g., applying) a via insulation layer covering the contact electrode, forming (e.g., applying) a via electrode connected to the contact electrode through the via insulation layer in the display area and a second pad connected to the first pad in the pad area, partially etching an upper portion of the first pad or the second pad while etching the via insulation layer in the pad area, and a forming a light-emitting element electrically connected to the via electrode.

In one or more embodiments, the forming (e.g., applying) of the via insulation layer may include forming (e.g., applying) a first via insulation layer covering the contact electrode, forming (e.g., applying) a second via insulation layer on the first via insulation layer, and forming (e.g., applying) a third via insulation layer on the second via insulation layer. The forming (e.g., applying) of the via electrode may include forming (e.g., applying) a first via electrode penetrating (extending through) the first via insulation layer and connected to the contact electrode and forming (e.g., applying) a second via electrode penetrating (extending through) the second via insulation layer and connected to the first via electrode.

In one or more embodiments, the forming (e.g., applying) of the second via electrode may include forming (e.g., applying) a third conductive layer on the second via insulation layer to cover the second pad in the pad area.

In one or more embodiments, the method may further include partially etching the upper portion of the second pad while etching a portion of the third conductive layer in the pad area.

In one or more embodiments, the second pad may have a sequentially stacked structure of a first metal layer, a second metal layer, and a third metal layer. The partially etching of the upper portion of the second pad while etching the portion of the third conductive layer may include etching the third metal layer of the second pad.

In one or more embodiments, the partially etching of the upper portion of the first pad or the second pad while etching the via insulation layer may include etching the second metal layer of the second pad while etching the third via insulation layer in the pad area.

In one or more embodiments, the third metal layer of the second pad may include titanium (Ti). The second metal layer of the second pad may include aluminum (Al).

In one or more embodiments, the forming (e.g., applying) of the first via electrode may include forming (e.g., applying) a second conductive layer on the first via insulation layer to cover the first pad in the pad area.

In one or more embodiments, the method may further include partially etching the upper portion of the first pad while etching a portion of the second conductive layer in the pad area.

In one or more embodiments, the first pad may have a sequentially stacked structure of a first metal layer, a second metal layer, and a third metal layer. The partially etching of the upper portion of the first pad while etching the portion of the second conductive layer may include etching the third metal layer of the first pad.

In one or more embodiments, the partially etching of the upper portion of the first pad or the second pad while etching the via insulation layer may include etching the second metal layer of the first pad while etching the second via insulation layer in the pad area.

In one or more embodiments, the third metal layer of the first pad may include titanium (Ti). The second metal layer of the first pad may include aluminum (Al).

In one or more embodiments, the method may further include forming (e.g., applying) a bottom metal layer on the portion of the base substrate in the display area before the forming (e.g., applying) of the active layer and forming (e.g., applying) a bottom contact connected to the bottom metal layer before the forming (e.g., applying) of the via insulation layer.

In one or more embodiments, the first pad may be formed (e.g., applied) together with the bottom contact.

In one or more embodiments, the via insulation layer may include an organic polymer material.

According to one or more embodiments of the present disclosure, a display device includes a base substrate including (e.g., defining) a display area and a pad area, a transistor structure arranged on the base substrate of the display area, a via electrode connected to the transistor structure, a light-emitting element electrically connected to the transistor structure through the via electrode, and a pad arranged on the base substrate in the pad area and having a sequentially stacked structure of a bottom pad, a first pad, and a second pad. The second pad partially contacts an upper portion of the first pad and the second pad has a smaller number of stacked layers or a smaller thickness than the first pad, or the second pad may have a greater number of the stacked layers or a greater thickness than the first pad (e.g., the second pad has a number of stacked layers different from a number of stacked layers of the first pad and/or has a thickness different from a thickness of the first pad, and the second pad partially contacts an upper portion of the first pad when the number of the stacked layers of the second pad is less than the number of the stacked layers of the first pad and/or the thickness of the second pad is less than the thickness of the first pad.).

In one or more embodiments, the number of the stacked layers or the thickness of the second pad may be greater than the number of the stacked layers or the thickness of the first pad and the second pad may entirely cover (e.g., may cover an entirety of) the upper portion and a side surface of the first pad.

In one or more embodiments, the via electrode may include a contact portion and a wiring portion connected to an upper portion of the contact portion, and the number of the stacked layers or the thickness of one of the first pad or the second pad may may be smaller than the number of stacked layers or a thickness of the wiring portion, respectively.

According to one or more embodiments, an electronic device includes a display device, a memory device, and a processor configured to control an operation of the display device by executing data included in the memory device. The display device may include a base substrate including (e.g., defining) a display area and a pad area, a transistor structure arranged on the base substrate in the display area, a via electrode connected to the transistor structure, a light-emitting element electrically connected to the transistor structure through the via electrode, and a pad arranged on the base substrate in the pad area and having a sequentially stacked structure of a bottom pad, a first pad, and a second pad. The second pad partially contacts an upper portion of the first pad and the second pad has a smaller number of stacked layers or a smaller thickness than the first pad, or the second pad may have a greater number of the stacked layers or a greater thickness than the first pad (e.g., the second pad has a number of stacked layers different from a number of stacked layers of the first pad and/or has a thickness different from a thickness of the first pad, and the second pad partially contacts an upper portion of the first pad when the number of the stacked layers of the second pad is less than the number of the stacked layers of the first pad and/or the thickness of the second pad is less than the thickness of the first pad.).

In one or more embodiments, the electronic device may include virtual reality glasses, augmented reality glasses, a smartphone, a tablet PC, a laptop, a TV, a desktop monitor, smart glasses, a head mounted display, a smart watch, or a vehicle display.

According to one or more embodiments of the present disclosure, the pad having a multi-layer structure may be formed by using a forming process for forming the contact electrode or the via electrode of the display area and an etching process of an insulation layer. Accordingly, the pad having the multi-layer structure may be formed without additional etching processes.

According to one or more embodiments of the present disclosure, damage of the bottom pad and excessive step height or thickness increase may be prevented or reduced and a physically and chemically stable pad may be formed. For example, portions or layers of pads may be etched during etching processes used to form contact or via holes and/or contact or via electrodes in the display area. This allows the thickness of the pad to be reduced without additional etching processes and the reduction in thickness of the pad reduces the likelihood of cracking and/or damage to the bottom pad of the pad, thus improving structural reliability of the display device.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a schematic plan view illustrating a pixel arrangement of a display device according to one or more embodiments of the present disclosure.

FIG. 2 is a schematic cross-sectional view illustrating the display device according to one or more embodiments of the present disclosure.

FIGS. 3 – 19 are schematic cross-sectional views explaining a method of manufacturing the display device according to one or more embodiments of the present disclosure.

FIG. 20 is an enlarged partial cross-sectional view illustrating a stacked structure of a contact electrode and a via electrode of the display device according to one or more embodiments of the present disclosure.

FIGS. 21 – 24 are schematic cross-sectional views explaining a method of manufacturing the display device according to one or more embodiments of the present disclosure.

FIG. 25 is a schematic cross-sectional view illustrating the display device according to one or more embodiments of the present disclosure.

FIGS. 26 – 32 are schematic cross-sectional views explaining a method of manufacturing the display device according to one or more embodiments of the present disclosure.

FIGS. 33 – 35 are schematic cross-sectional views explaining a method of manufacturing a display device according to one or more embodiments of the present disclosure.

FIG. 36 is a schematic cross-sectional view illustrating the display device according to one or more embodiments of the present disclosure.

FIG. 37 is a schematic cross-sectional view illustrating the display device according to one or more embodiments of the present disclosure.

FIG. 38 is an equivalent circuit diagram of the display device according to one or more embodiments of the present disclosure.

FIG. 39 is a block diagram illustrating an electronic device according to one or more embodiments of the present disclosure.

FIG. 40 shows schematic diagrams illustrating the electronic device of FIG. 39 according to various embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

Unless otherwise noted, like reference numerals denote like elements throughout the attached drawings and the written description, and thus, duplicative descriptions thereof may not be provided.

It will be understood that when an element, such as an area, layer, film, region or portion, is referred to as being “on,” “connected to,” or “coupled to” another element, it can be directly on, connected to, or coupled to the other element, or one or more intervening elements may be present. In contrast, when an element or layer is referred to as being “directly on,” “directly connected to”, “directly coupled to”, or “immediately adjacent to” another element or layer, there are no intervening elements or layers present. In addition, it will also be understood that when an element is referred to as being “between” two elements, it can be the only element between the two elements, or one or more intervening elements may also be present.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the drawings, the relative sizes (e.g., including lengths, widths and thicknesses) of elements, layers, and regions may be exaggerated for clarity.

Spatially relative terms, such as “on,” “below,” “lower,” “under,” “above,” “upper,” and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

As used herein, the singular forms “a,” “an” and “the” are intended to include the plural forms as well, unless the context clearly indicates otherwise. It will be further understood that the terms “comprises,” “comprising,” “includes,” “including,” “have,” “having,” “contain,” and “containing,” when used in this specification, specify the presence of the stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having,” “contain/containing” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, the term “and/or” includes any and all combinations of one or more of the associated listed items. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions "at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As used herein, the terms “use,” “using,” and “used” may be considered synonymous with the terms “utilize,” “utilizing,” and “utilized,” respectively.

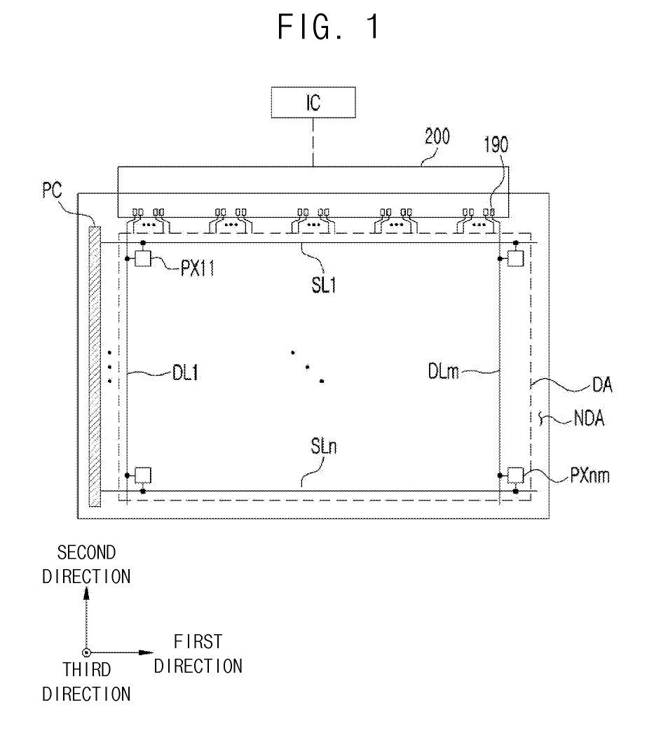

FIG. 1 is a schematic plan view illustrating a pixel arrangement of a display device according to one or more embodiments of the present disclosure.

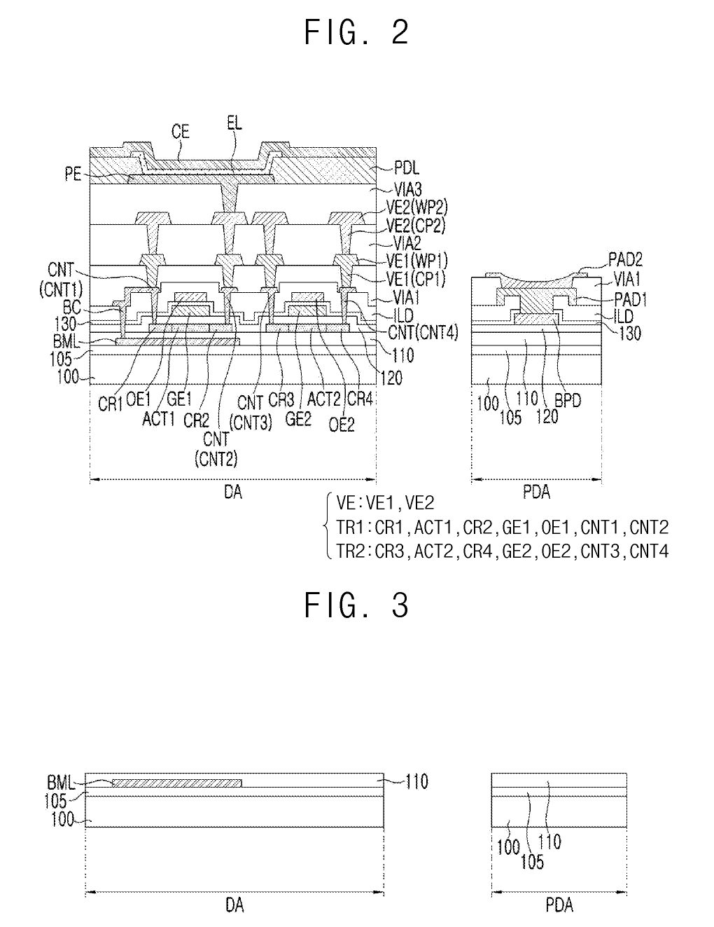

In FIG. 1, a first direction and a second direction may refer to two directions that are normal (e.g., perpendicular) to each other and parallel to an upper surface of a base substrate 100 (see, e.g., FIG. 2) or a display surface of the display device. For example, the first direction may correspond to an X-direction (a row direction) of the display device, and the second direction may correspond to a Y-direction (a column direction) of the display device.

A third direction may be normal (e.g., perpendicular) to the first direction and the second direction. The third direction may correspond to a Z-direction (a thickness direction) of the display device.

Referring to FIG. 1, a plurality of pixels PX11–PXnm may be arranged in a display area DA of the display device or the base substrate 100 (e.g., the display device and/or of the base substrate may be referred to as defining the display area DA).

According to one or more embodiments, a pixel circuit, which includes scan lines (or gate lines) SL1–SLn forming first to n-th rows and data lines DL1–DLm forming first to m-th columns, may be arranged on the base substrate 100. Each of the pixels PX11–PXnm may be connected to a corresponding first to n-th row scan line among the plurality of scan lines SL1–SLn and to a corresponding first to m-th column data line among the plurality of data lines DL1–DLm.

For example, the scan lines SL1–SLn may be connected to a gate electrode included in a thin-film transistor (TFT). The data lines DL1–DLm may be connected, for example, to a contact electrode (e.g., a first contact electrode CNT1 or a third contact electrode CNT3) provided as a source electrode.

Each of the pixels PX11–PXnm may include a pixel circuit, which includes a transistor structure, and a light-emitting element, as will be described in more detail later. In one or more embodiments, the pixel circuit may further include wirings such as a power line and a ground line, and/or the like.

In FIG. 1, the data lines DL1–DLm are illustrated as extending in the second direction, and the scan lines SL1–SLn are illustrated as extending in the first direction, but the data lines DL1–DLm and the scan lines SL1–SLn are not necessarily limited thereto.

A peripheral circuit PC may be arranged in a non-display area NDA of the display device. For example, the peripheral circuit PC may include a gate driving circuit. The gate driving circuit may be integrated into the display device through an oxide silicon gate (OSG) driving circuit process, an amorphous silicon gate (ASG) driving circuit process, or a polysilicon gate (PSG) driving circuit process.

The display device may further include a printed circuit board 200. Pads 190 of the pixel circuit (e.g., of the data lines DL1-DLm) may be gathered at one side of the non-display area NDA. The non-display area NDA may include a pad area PDA (see, e.g., FIG. 2), and the pads 190 may be arranged in the pad area PDA.

The printed circuit board 200 may be electrically connected to the pixel circuit through the pads 190. For example, the printed circuit board 200 may be electrically connected to the pads 190 through a heat-pressing process using a conductive intermediary structure such as an anisotropic conductive film (ACF).

Through the printed circuit board 200, the pads 190 and a driving circuit device IC may be electrically connected. The driving circuit device IC may include an integrated circuit chip. In one or more embodiments, the integrated circuit chip may be mounted on the printed circuit board 200 in a chip-on-film (COF) form.

The driving circuit device IC may include a driving circuit of the display device and a driving circuit of an electronic device (for example, an application processor (AP) chip). The driving circuit device IC may further include a circuit board such as a main board on which a chip including the driving circuit is mounted.

FIG. 2 is a schematic cross-sectional view illustrating the display device according to one or more embodiments of the present disclosure.

Referring to FIG. 2, the display device or the base substrate 100 may include a display area DA and a pad area PDA (e.g., the display device and/or of the base substrate may be referred to as defining the display area DA and the pad area PDA). As described with reference to FIG. 1, the pad area PDA may be included in the non-display area NDA.

On the base substrate 100 of the display area DA, the pixel circuit including the transistor structure TR1 and TR2, and the light-emitting element electrically connected to the pixel circuit may be included. The light-emitting element may be electrically connected to the transistor structure through a via electrode VE.

The transistor structure may include a first transistor structure TR1 and a second transistor structure TR2. The first transistor structure TR1 and the second transistor structure TR2 may respectively serve as a driving transistor and a switching transistor of the corresponding pixel.

The base substrate 100 may be provided as a back-plane substrate of the display device or the display panel. A glass substrate or a plastic substrate may be used as the base substrate 100.

In one or more embodiments, the base substrate 100 may include a polymer material having transparency and a certain degree of flexibility. For example, the base substrate 100 may include a polymer material such as polyimide, polysiloxane, epoxy resin, acrylic resin, or polyester. In one or more embodiments, the base substrate 100 may include polyimide.

In one or more embodiments, the glass substrate may be used as the base substrate 100.

A barrier layer 105 may be formed on an upper surface of the base substrate 100. The barrier layer 105 may block or reduce moisture penetration through the base substrate 100, and may block or reduce impurity diffusion between the base substrate 100 and a structure formed on the base substrate 100. The barrier layer 105 may entirely cover the upper surface of the base substrate 100 (e.g., the barrier layer 105 may cover the entirety of the upper surface of the base substrate 100).

For example, the barrier layer 105 may include an inorganic insulating material such as silicon oxide, silicon nitride, or silicon oxynitride. These may be used alone or in combination of two or more. In one or more embodiments, the barrier layer 105 may have a stacked structure including a silicon oxide film and a silicon nitride film. In one or more embodiments, the barrier layer 105 may include an organic layer and may have a multi-layer structure of the organic layer and an inorganic layer.

A bottom metal layer BML may be arranged on the barrier layer 105. The bottom metal layer BML may be arranged under the first transistor structure TR1 and may overlap the first transistor structure TR1 in the thickness direction.

The bottom metal layer BML may include a metal such as silver (Ag), tungsten (W), molybdenum (Mo), aluminum (Al), copper (Cu), titanium (Ti), chromium (Cr), nickel (Ni), tantalum (Ta), molybdenum (Mo), platinum (Pt), or palladium (Pd), or an alloy containing at least one of these.

The bottom metal layer BML may serve as a blocking layer for blocking or reducing external light incident on the first transistor structure TR1. The bottom metal layer BML may also serve as a bias electrode. In one or more embodiments, the bottom metal layer BML may be a floating electrode in a form of an island which is separated from other wirings or electrodes. In one or more embodiments, the bottom metal layer BML may be provided as a back gate or a source-sink electrode.

A buffer layer 110 covering the bottom metal layer BML may be formed on the barrier layer 105. The buffer layer 110 may additionally prevent or reduce the likelihood of impurity penetration into the active layers ACT1 and ACT2 of the transistor structures TR1 and TR2. The buffer layer 110 may include an inorganic insulating material such as silicon nitride, silicon oxide, and/or silicon oxynitride. The buffer layer 110 may have a single-layer structure or a multi-layer structure including the inorganic insulating materials.

The first transistor structure TR1 and the second transistor structure TR2 may be arranged on the buffer layer 110. The first transistor structure TR1 may include a first active layer ACT1, a first gate electrode GE1, and a first overlap electrode OE1. The second transistor structure TR2 may include a second active layer ACT2, a second gate electrode GE2, and a second overlap electrode OE2.

Gate insulation layers 120 and 130 may be commonly included in (may be included across both of) the first transistor structure TR1 and the second transistor structure TR2. Each of the first transistor structure TR1 and the second transistor structure TR2 may further include contact electrodes CNT.

The first and second active layers ACT1 and ACT2 may be arranged on the buffer layer 110.

The active layers ACT1 and ACT2 may each include a silicon compound such as polysilicon or amorphous silicon. In some areas of the active layers ACT1 and ACT2, a p-type (kind) dopant or an n-type (kind) dopant may be doped, and a source area, a drain area, and a channel area may be included.

The active layers ACT1 and ACT2 may include an oxide semiconductor such as indium gallium zinc oxide (IGZO), zinc tin oxide (ZTO), or indium tin zinc oxide (ITZO).

A first gate insulation layer 120 may be formed on the active layers ACT1 and ACT2, and the first gate electrode GE1 and the second gate electrode GE2 may be stacked on the first gate insulation layer 120. The first gate insulation layer 120 may extend continuously across the plurality of pixels and may serve as a common layer for a plurality of transistor structures.

Alternatively, in one or more embodiments, the first gate insulation layer 120 may partially cover each active layer ACT1 and ACT2 and may be formed in an independent pattern for each of the transistor structures.

The first gate electrode GE1 may overlap the channel area of the first active layer ACT1 in the third direction (thickness direction). The second gate electrode GE2 may overlap the channel area of the second active layer ACT2 in the third direction (thickness direction). A scan signal may be delivered through the gate electrodes GE1 and GE2 from the scan line.

In one or more embodiments, the p-type (kind) or the n-type (kind) dopants may be implanted into the active layers ACT1 and ACT2 through an ion implantation process using the gate electrodes GE1 and GE2 as an ion implantation mask. Accordingly, a first contact area CR1 and a second contact area CR2 may be formed on one side and the other side of the first active layer ACT1, respectively. The first contact area CR1 and the second contact area CR2 may correspond to a source area and a drain area, respectively. A third contact area CR3 and a fourth contact area CR4 may be formed on one side and the other side of the second active layer ACT2. The third contact area CR3 and the fourth contact area CR4 may correspond to the source area and the drain area, respectively.

In one or more embodiments, the first gate insulation layer 120 may be formed in a pattern covering the channel area through an etching process using the gate electrode GE1 and GE2 as an etching mask. When the active layer ACT1 and ACT2 include the oxide semiconductor, hydrogen H included in the second gate insulation layer 130 may be diffused or move into the active layers ACT1 and ACT2 during formation of the second gate insulation layer 130. Accordingly, a carrier concentration may increase by the hydrogen, so that a contact area CR1, CR2, CR3, and CR4 may be formed at side portions of the active layer ACT1 and ACT2.

The second gate insulation layer 130 may cover the gate electrodes GE1 and GE2 on the first gate insulation layer 120. Overlap electrodes OE1 and OE2 may be formed on the second gate insulation layer 130. A first overlap electrode OE1 may overlap the first gate electrode GE1 in the thickness direction, and a second overlap electrode OE2 may overlap the second gate electrode GE2 in the thickness direction.

In one or more embodiments, the overlap electrodes OE1 and OE2 may be provided as upper gate electrodes. In one or more embodiments, storage capacitors may be defined by the gate electrodes GE1 and GE2, the second gate insulation layer 130, and the overlap electrodes OE1 and OE2 (e.g., the first gate electrode GE1, the second gate insulation layer 130, and the first overlap electrode OE1 may define a first storage capacitor, and the second gate electrode GE2, the second gate insulation layer 130, and the second overlap electrode OE2 may define a second storage capacitor). An interlayer insulation layer ILD covering the overlap electrodes OE1 and OE2 may be formed on the second gate insulation layer 130.

In one or more embodiments, at least one of the overlap electrodes OE1 and OE2 may not be provided. In such embodiments, the second gate insulation layer 130 and the interlayer insulation layer ILD may be formed substantially as a single interlayer insulating layer.

The gate insulation layers 120 and 130 and the interlayer insulating layer ILD may each include an inorganic insulating material such as silicon oxide, silicon nitride, silicon oxynitride, a metal oxide, and/or the like.

The gate electrodes GE1 and GE2 and the overlap electrodes OE1 and OE2 may each include a metal such as Ag, Mg, Al, W, Cu, Ni, Cr, Mo, Ti, Pt, Ta, Nd, Sc, and/or the like, an alloy thereof, or a nitride thereof. In one or more embodiments, each of the gate electrodes GE1 and GE2 and/or the overlap electrodes OE1 and OE2 may have a multi-layer structure (e.g., a Ti layer–Al layer–Ti layer).

On the interlayer insulating layer ILD, contact electrode CNT1, CNT2, CNT3, and CNT4 which contact or are electrically connected to at least one of the active layers ACT1 and/or ACT2 may be formed.

The contact electrodes CNT may include the first contact electrode CNT1 which is connected to and/or contacts the first contact area CR1 of the first active layer ACT, and the second contact electrode CNT2 which is connected to and/or contacts the second contact area CR2 of the first active layer ACT. The first contact electrode CNT1 and the second contact electrode CNT2 may respectively serve as a source electrode and a drain electrode of the first transistor structure TR1.

The contact electrodes CNT may include the third contact electrode CNT3 which is connected to and/or contacts the third contact area CR3 of the second active layer ACT2 and the fourth contact electrode CNT4 which is connected to and/or contacts the fourth contact area CR4 of the second active layer ACT2. The third contact electrode CNT3 and the fourth contact electrode CNT4 may be respectively provided as a source electrode and a drain electrode of the second transistor structure TR2.

In one or more embodiments, the display device may further include a bottom contact BC which contacts and/or is electrically connected to the bottom metal layer BML by penetrating (extending through) the interlayer insulation layer ILD and the buffer layer 110. The bottom contact BC may also penetrate (extend through) the gate insulation layers 120 and 130.

In one or more embodiments, the bottom contact BC may be connected to the first contact electrode CNT1 which is provided as a source contact. In one or more embodiments, the bottom contact BC may be provided as a source-sink contact.

On the interlayer insulation layer ILD and the contact electrodes CNT1, CNT2, CNT3, and CNT4, via insulation layers VIA and via electrodes VE may be stacked.

A first via insulation layer VIA1 may be formed on the interlayer insulation layer ILD and may cover the contact electrodes CNT1, CNT2, CNT3, and CNT4. First via electrodes VE1 may be formed on the first via insulation layer VIA1 and may be connected to and/or contact each of the contact electrode CNT1, CNT2, CNT3, and CNT4.

The first via electrodes VE1 may include first wiring portions WP1 which are arranged on the first via insulation layer VIA1 and first contact portions CP1 which penetrates (extends through) the first via insulation layer VIA1 and are connected to the contact electrodes CNT1, CNT2, CNT3, and CNT4. Each of the first wiring portions WP1 and the first contact portions CP1, respectively, may be formed substantially as an integral single member.

The second via insulation layer VIA2 may be formed on the first via insulation layer VIA1 and may cover the first via electrodes VE1. The second via electrodes VE2 may be formed on the second via insulation layer VIA2 and may be connected and/or contact to the first via electrodes VE1.

The second via electrodes VE2 may include second wiring portions WP2 which are arranged on the second via insulation layer VIA2 and second contact portions CP2 which penetrate (extend through) the second via insulation layer VIA2 and are connected to the first via electrodes VE1. Each of the second wiring portions WP2 and the second contact portions CP2, respectively, may be formed substantially as an integral single member.

The third via insulation layer VIA3 may be formed on the second via insulation layer VIA2 and may cover the second via electrodes VE2.

Each of the first to third via insulation layers VIA1, VIA2, and VIA3 may include an organic polymer material. For example, the first to third via insulation layers VIA1, VIA2, and VIA3 may include polyimide, epoxy-based resin, acrylic-based resin, polyester, siloxane-based resin, or benzocyclobutene (BCB).

The first and second via electrodes VE1 and VE2 may include the above-described metal or alloy described with respect to the gate electrodes.

On the third via insulation layer VIA3, the light-emitting element (e.g., each light-emitting element of a plurality of light-emitting elements), which includes a pixel electrode PE, an emission portion EL, and a counter electrode CE, may be stacked. In one or more embodiments, the pixel electrode PE may be electrically connected to the second contact electrode CNT2 of the first transistor structure TR1 through the first via electrode VE1 and the second via electrode VE2. The pixel electrode PE may include a via portion which penetrates (extends through) the third via insulation layer VIA3 and is connected to and/or contacts to the second wiring portion WP2 of the second via electrode VE2.

The pixel electrode PE may be provided as an anode and may include a high work-function conductive material which promotes hole injection. The pixel electrode PE may be provided as a transmissive electrode. The pixel electrode PE may include a transparent conductive oxide such as indium tin oxide (ITO), indium zinc oxide (IZO), zinc oxide (ZnO), and/or indium tin zinc oxide (ITZO).

The pixel electrode PE may also be provided as a semi-transmissive electrode or a reflective electrode. The pixel electrode PE may include a metal selected from among Ag, Mg, Cu, Al, Pt, Pd, Au, Ni, Nd, Ir, Vr, Li, Ca, LiF, Mo, Ti, W, In, Sn, and Zn, or an alloy of two or more of these.

The pixel electrode PE may have a single-layer structure or a multi-layer structure. For example, the pixel electrode PE may have a three-layer structure such as ITO/Ag/ITO or ITO/Al/ITO.

A pixel-defining layer PDL may be formed on the third via insulation layer VIA3 and an upper surface of the pixel electrode PE may be at least partially exposed by the pixel-defining layer PDL. The pixel-defining layer PDL may cover a peripheral portion of the pixel electrode PE.

An emission area (or a pixel area) may be defined by a sidewall of the pixel-defining layer PDL. For example, a green emission area, a blue emission area, and a red emission area may be defined and separated by the pixel-defining layer PDL. Accordingly, the light-emitting elements may include a blue light-emitting element, a green light-emitting element, and a red light-emitting element.

In one or more embodiments, the light-emitting elements may all be white light-emitting elements or blue light-emitting elements.

The pixel-defining layer PDL may include, for example, an organic material such as polysiloxane resin, polyimide resin, acrylic resin, and/or the like. The pixel-defining layer PDL may further include a colorant such as a black pigment and/or black dye dispersed in the resin material.

On the pixel electrode PE and the pixel-defining layer PDL, the emission portion EL may be disposed. The emission portion EL may include an organic emission layer which is independently patterned for a red pixel, a green pixel, and a blue pixel to generate different colored lights for each pixel.

In one or more embodiments, the emission portion EL may extend continuously and commonly across a plurality of pixels. In such embodiments, the emission portion EL may include a white emission layer or a blue emission layer. In one or more embodiments, the emission portion EL may include emission layers corresponding to a plurality of emission layers, where the emission layers correspond to different colored lights, and the emission portion EL may include a stacked body having a tandem structure including the emission layers.

On the emission portion EL, the counter electrode CE may be disposed. The counter electrode CE may be a common electrode which is provided continuously and commonly across a plurality of emission areas or pixels.

The counter electrode CE may be provided as an electron injection electrode or a cathode. The counter electrode CE may include a metal, an alloy, an electrically conductive compound which has a low work function, and/or the like.

For example, the counter electrode CE may include lithium (Li), silver (Ag), magnesium (Mg), aluminum (Al), aluminum-lithium (Al-Li), calcium (Ca), magnesium-indium (Mg-In), magnesium-silver (Mg-Ag), ytterbium (Yb), silver-ytterbium (Ag-Yb), ITO, IZO, and/or the like. Theses may be used alone or in combination of two or more.

The counter electrode CE may be provided as a transmissive electrode, a semi-transmissive electrode, or a reflective electrode. The counter electrode CE may have a single-layer structure or a multi-layer structure.

The emission portion EL may further include a hole transport layer and an electron transport layer. According to one or more embodiments, the hole transport layer, the emission layer, the electron transport layer, and the counter electrode CE may be sequentially stacked from the upper surface of the pixel electrode PE.

The hole transport layer may include a hole transport material such as m-MTDATA (4,4',4"-[tris(3-methylphenyl)phenylamino] triphenylamine), TDATA (4,4',4"-tris(N,N-diphenylamino)triphenylamine), 2-TNATA (4,4',4"-tris[N(2-naphthyl)-N-phenylamino]-triphenylamine), NPB (N,N'-di(naphthalene-1-yl)-N,N'-diphenyl-benzidine), TPD (N,N'-bis(3-methylphenyl)-N,N'-diphenyl-[1,1'-biphenyl]-4,4'-diamine), TCTA (4,4',4"-tris(N-carbazolyl)triphenylamine), PEDOT/PSS (poly(3,4-ethylenedioxythiophene)/poly(4-styrenesulfonate)), and/or the like.

The electron transport layer may include an electron transport material such as an anthracene-based compound, Alq3 (tris(8-hydroxyquinolinato)aluminum), TPBi (1,3,5-Tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1'-biphenyl-4-olato)aluminum), and/or the like.

In one or more embodiments, a hole injection layer may be further arranged between the pixel electrode PE and the hole transport layer, and an electron injection layer may be further arranged between the counter electrode CE and the electron transport layer.

In one or more embodiments, the emission layer, which is included in the emission portion EL, may be selectively patterned in an emission area which is defined by the pixel-defining layer PDL. Accordingly, the emission layer may be separated in an island form for each of the plurality of pixels.

In one or more embodiments, layers included in the emission portion EL (for example, the hole transport layer and the electron transport layer) may extend continuously and commonly across a plurality of emission areas and the entire upper surface of the pixel-defining layer PDL.

An organic light-emitting diode OLED device may be formed by the pixel electrode PE, the emission portion EL, and the counter electrode CE, which are described above.

An encapsulation layer may be formed on the counter electrode CE. The encapsulation layer may be arranged on the pixel-defining layer PDL and the light-emitting elements and may protect the light-emitting elements from moisture or oxygen.

The encapsulation layer may include an inorganic film including silicon nitride (SiNₓ), silicon oxide (SiOₓ), indium tin oxide, indium zinc oxide, or a (e.g., any suitable) combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (e.g., polymethyl methacrylate, polyacrylic acid, and/or the like), an epoxy resin (e.g., AGE (aliphatic glycidyl ether) and/or the like), or a (e.g., any suitable) combination thereof; and/or a (e.g., any suitable) combination of the inorganic film and the organic film.

The encapsulation layer may be formed as a single layer or as a multi-layer structure. In one or more embodiments, the encapsulation layer may have a sequentially stacked structure of a first inorganic layer, an organic layer, and a second inorganic layer.

In one or more embodiments, a color control layer which overlaps the emission portion EL may be arranged on the encapsulation layer. The color control layer may include a color conversion layer including quantum dots and/or a color filter.

The pad 190 (see, e.g., FIG. 1) may be formed on the pad area PDA of the display device or the base substrate 100.

The pad 190 may include a bottom pad BPD, a first pad PAD1, and a second pad PAD2. According to one or more embodiments, the bottom pad BPD, the first pad PAD1, and the second pad PAD2 may be sequentially stacked from an upper surface of the first gate insulation layer 120.

The bottom pad BPD may be arranged on the first gate insulation layer 120 and may be formed of a layer which includes the same material as the gate electrodes GE1 and GE2 (e.g., the bottom pad BPD and the gate electrodes GE1 and GE2 may be formed concurrently in the same layer). In one or more embodiments, the bottom pad BPD and the gate electrode GE1 and GE2 may have substantially a same thickness.

The first pad PAD1 may contact an upper surface of the bottom pad BPD and may be on the second gate insulation layer 130 and the interlayer insulation layer ILD. The first pad PAD1 may be formed of a layer which includes the same material as the contact electrode CNT (e.g., the first pad PAD1 and the contact electrode CNT may be formed concurrently in the same layer).

The first via insulation layer VIA1 may partially cover the first pad PAD1. The second pad PAD2 may contact the upper surface of the first pad PAD1 and may be on the first via insulation layer VIA1, and the second pad PAD2 may contact a part of the upper surface of the first pad PAD1 adjacent to the first via insulation layer VIA1.

According to one or more embodiments, a thickness of the second pad PAD2 may be less than a thickness of the first pad PAD1, and the number of stacked layers of the second pad PAD2 may be less than the number of stacked layers of the first pad PAD1.

In one or more embodiments, a thickness of the second pad PAD2 may be less than a thickness of each of the first wiring portions WP1 of the first via electrodes VE1.

As described above, cracks and damage of the bottom pad BPD caused by an excessive increase in the number of stacked layers included in the pad 190 may be prevented or reduced by reducing the thickness of the second pad PAD2. In addition, in one or more embodiments, conductivity through the pad 190 may be improved by reducing the number of interlayer interfaces included in the pad 190.

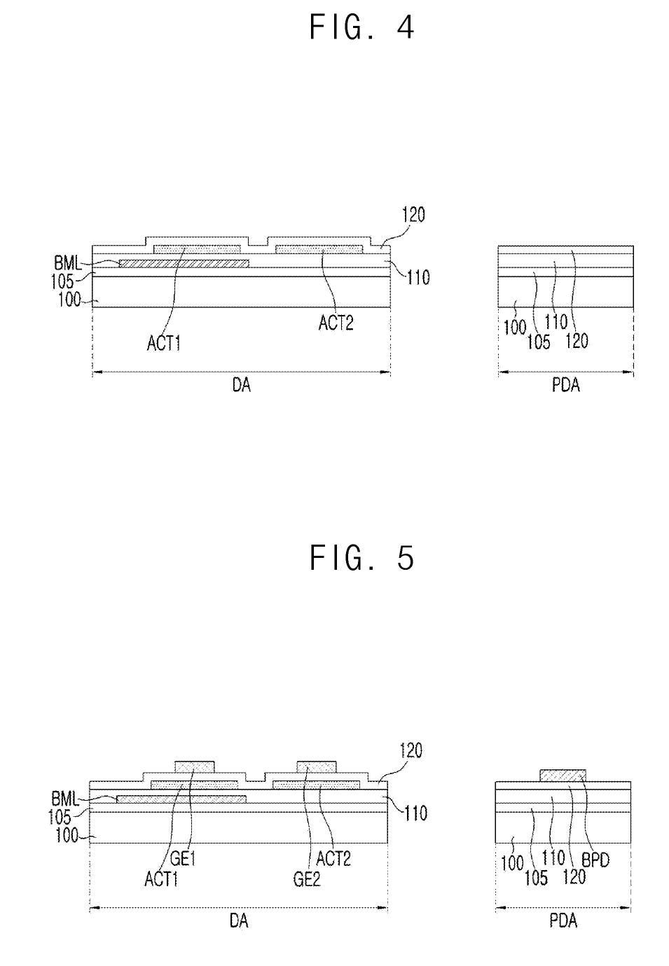

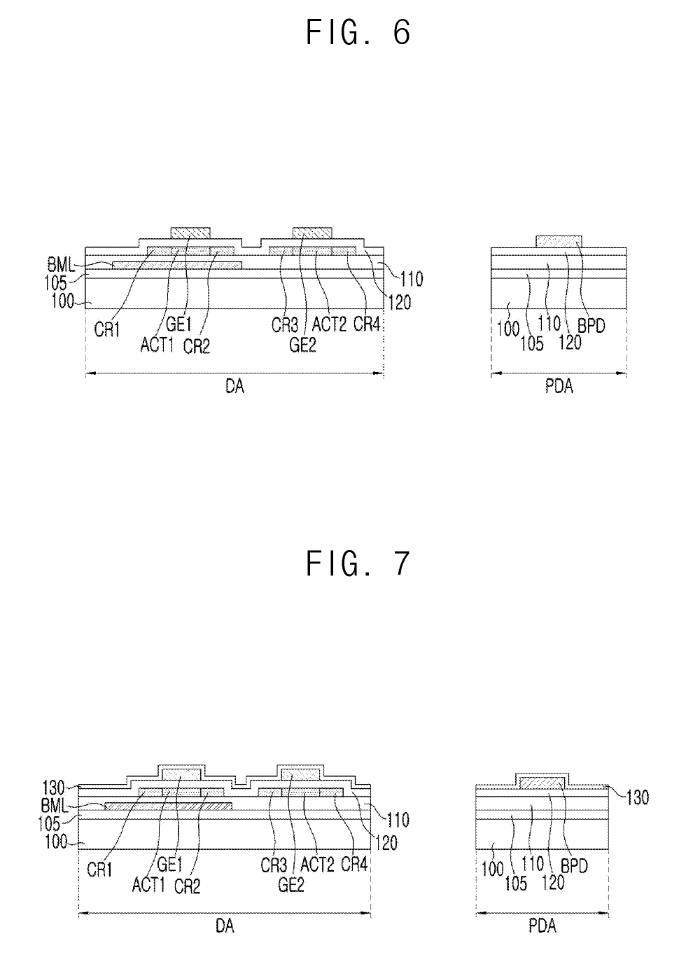

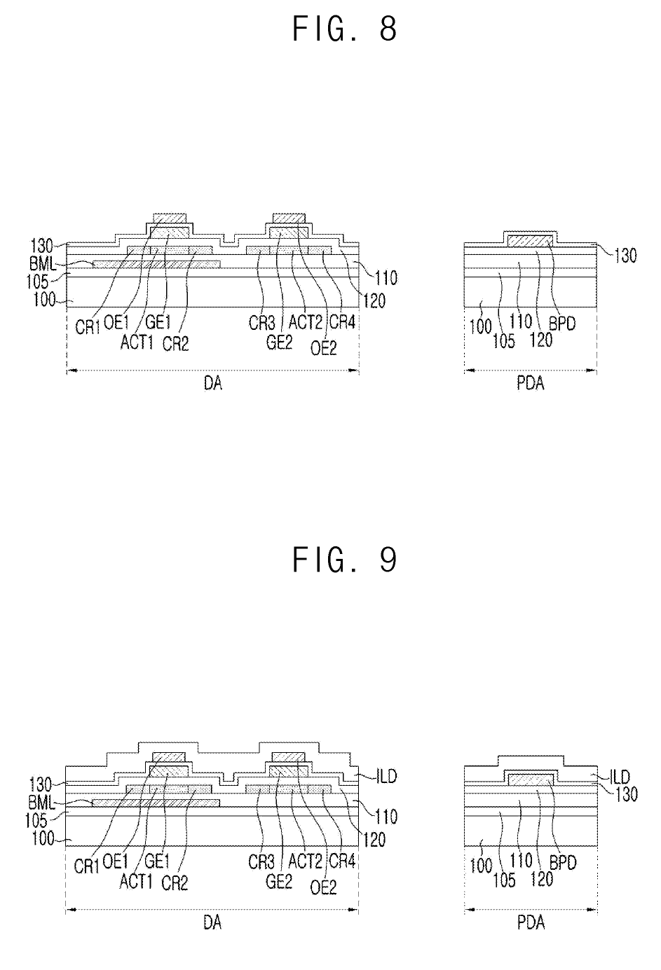

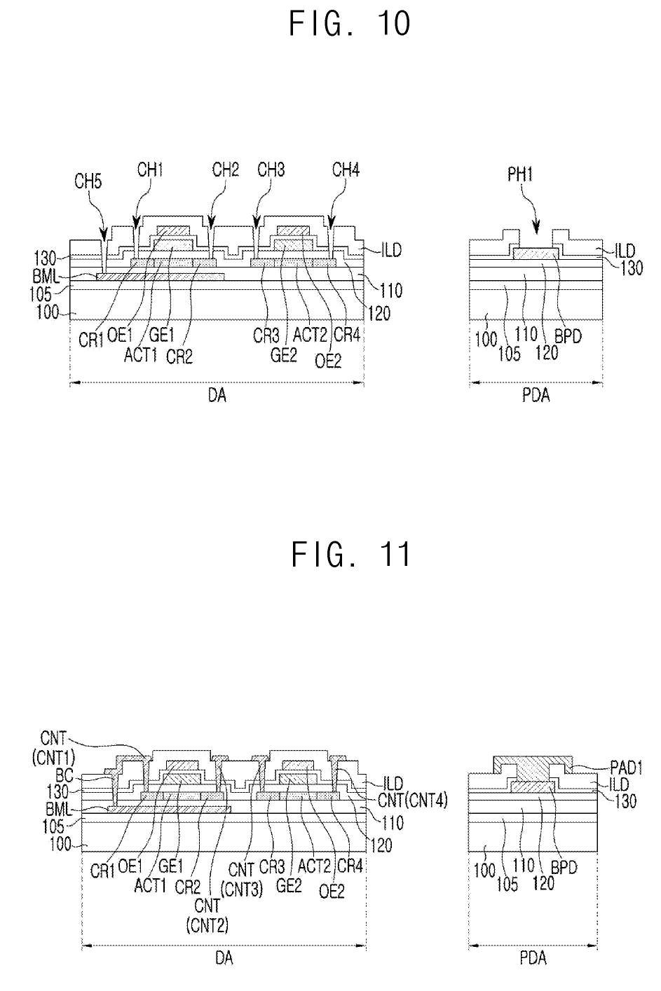

FIGS. 3-19 are schematic cross-sectional views explaining a method of manufacturing the display device according to one or more embodiments of the present disclosure. FIGS. 3 - 19 are cross-sectional views explaining the method of manufacturing the display device described with reference to FIG. 2.

Referring to FIG. 3, the barrier layer 105 may be formed on the base substrate 100, and the bottom metal layer BML may be formed on the barrier layer 105 of the display area DA. Thereafter, the buffer layer 110 which covers the bottom metal layer BML may be formed on the barrier layer 105.

The barrier layer 105 and the buffer layer 110 may be formed through an application or deposition process such as a chemical vapor deposition (CVD) process so that the barrier layer 105 and the buffer layer 110 include the inorganic insulation material which is described above. The barrier layer 105 and the buffer layer 110 may be formed continuously and commonly on the display area DA and the pad area PDA.

The bottom metal layer BML may be formed by forming a conductive layer including the metal or alloy, which are described above, through an application or deposition process such as a sputtering process or a physical vapor deposition PVD process, and patterning the conductive layer through a photolithography and etching process.

Referring to FIG. 4, the active layer including the first active layer ACT1 and the second active layer ACT2 may be formed on the buffer layer 110 of the display area DA.

For example, a semiconductor layer including a silicon-based compound or an oxide semiconductor may be formed on the buffer layer 110 through an application or deposition process such as a sputtering process or a PVD process. Thereafter, the semiconductor layer may be patterned through a photolithography etching process, so that the first active layer ACT1 and the second active layer ACT2 may be formed.

Thereafter, the first gate insulation layer 120 which covers the active layer ACT1 and ACT2 may be formed on the buffer layer 110. For example, the first gate insulation layer 120 may be formed by applying or depositing the inorganic insulation material, which is described above, through a CVD process.

The first gate insulation layer 120 may be formed continuously and commonly on the display area DA and the pad area PDA.

Referring to FIG. 5, the gate electrode GE1 and GE2 may be formed on the first gate insulation layer 120 of the display area DA, and the bottom pad BPD may be formed on the first gate insulation layer 120 of the pad area PDA.

According to one or more embodiments, the gate conductive layer including the metal or alloy, which are described above, may be formed on the first gate insulation layer 120 through an application or deposition process such as a sputtering process or a PVD process. The gate conductive layer may be patterned through a photolithography etching process, so that the first gate electrode GE1, the second gate electrode GE2, and the bottom pad BPD may be formed.

As described above, the bottom pad BPD may be formed through the same etching process using the same material layer as the gate electrode GE1 and GE2. In one or more embodiments, the first gate electrode GE1, the second gate electrode GE2, and the bottom pad BPD may have a same stack structure. In one or more embodiments, the first gate electrode GE1, the second gate electrode GE2, and the bottom pad BPD may have a three-layer structure of a Ti layer-Al layer-Ti layer.

Referring to FIG. 6, the contact areas may be formed at the side portions of the active layers ACT1 and ACT2.

According to one or more embodiments, the first contact area CR1 and the second contact area CR2 may be formed at one side portion and the other side portion of the first active layer ACT1, respectively, through an ion implantation process using the gate electrode GE1 and GE2 as an ion implantation mask. The third contact area CR3 and the fourth contact area CR4 may be formed at one side portion and the other side portion of the second active layer ACT2, respectively.

Referring to FIG. 7, the second gate insulation layer 130 which covers the gate electrode GE1 and GE2 and the bottom pad BPD may be formed on the first gate insulation layer 120.

In one or more embodiments, in the display area DA, the first gate insulation layer 120 may be formed as a patterned layer which partially overlaps the active layer ACT1 and ACT2 below the gate electrodes GE1 and GE2. In such embodiments, if (e.g., when) the active layer ACT1 and ACT2 includes an oxide semiconductor, hydrogen of the second gate insulation layer 130 may be transferred to the active layer ACT1 and ACT2 (e.g., a defect site induced by etching of the first gate insulation layer 120), so that the contact area CR1, CR2, CR3, and CR4 may be formed.

Referring to FIG. 8, the overlap electrodes OE1 and OE2 may be formed on the second gate insulation layer 130 of the display area DA.

For example, an overlap conductive layer including the metal or alloy, which are described above, may be formed on the second gate insulation layer 130 through a sputtering process or a PVD process, and the overlap conductive layer may be patterned through a photolithography etching process, so that the overlap electrodes OE1 and OE2 may be formed.

According to one or more embodiments, the first overlap electrode OE1 and the second overlap electrode OE2 may be formed on the second gate insulation layer 130 so that the first overlap electrode OE1 and the second overlap electrode OE2 overlap the first gate electrode GE1 and the second gate electrode GE2, respectively.

Referring to FIG. 9, the interlayer insulation layer ILD which covers the overlap electrode OE1 and OE2 may be formed on the second gate insulation layer 130.

The interlayer insulation layer ILD may be formed so that the interlayer insulation layer ILD includes the inorganic insulation material, which is described above, for example through a CVD process. The interlayer insulation layer ILD may be formed continuously and commonly on the display area DA and the pad area PDA.

Referring to FIG. 10, the first to fourth contact holes CH1, CH2, CH3, and CH4 which expose the first to fourth contact areas CR1, CR2, CR3, and CR4 of the active layer ACT1 and ACT2, respectively, may be formed by partially etching the interlayer insulation layer ILD on the display area DA.

In one or more embodiments, the fifth contact hole CH5, which exposes the bottom metal layer BML, may be formed by partially etching the interlayer insulation layer ILD.

The first to fourth contact holes CH1, CH2, CH3, and CH4 may penetrate (extend through) the interlayer insulation layer ILD, the second gate insulation layer 130, and the first gate insulation layer 120 together. The fifth contact hole CH5 may penetrate (extend through) the interlayer insulation layer ILD, the second gate insulation layer 130, the first gate insulation layer 120, and the buffer layer 110 together.

According to one or more embodiments, through the etching process for forming the contact holes, which is described above, the first pad hole PH1 which exposes the upper surface of the bottom pad BPD may be formed on the pad area PDA.

The first pad hole PH1 may penetrate (extend through) the interlayer insulation layer ILD and expose the bottom pad BPD. The first pad hole PH1 may penetrate (extend through) the interlayer insulation layer ILD and the second gate insulation layer 130 together.

Referring to FIG. 11, a first conductive layer may be formed on the interlayer insulation layer ILD. The first conductive layer may fill the contact holes CH1, CH2, CH3, CH4, and CH5. The first conductive layer may be formed through an application or deposition process such as a sputtering process or a PVD process so that the first conductive layer may include the metal or alloy which are described above.

A portion of the first conductive layer, which is formed on the upper surface of the interlayer insulation layer ILD, may be partially removed through a photolithography etching process, so that the contact electrodes CNT1, CNT2, CNT3, and CNT4, which contact and/or are connected to the first to fourth contact areas CR1, CR2, CR3, and CR4, respectively, in the first to fourth contact holes CH1, CH2, CH3, and CH4, may be formed. The bottom contact BC, which contacts or is connected to the bottom metal layer BML, may be formed in the fifth contact hole CH5.

On the pad area PDA, the first pad PAD1 may be formed through the application/deposition and etching processes, which are described above, using the first conductive layer. The first pad PAD1 may be formed on the interlayer insulation layer ILD, may fill the first pad hole PH1, and may contact and/or be connected to the bottom pad BPD.

Referring to FIG. 12, the first via insulation layer VIA1 may be formed on the interlayer insulation layer ILD. The first via insulation layer VIA1 may be formed through a coating process such as a spin-coating process, and the first via insulation layer VIA1 may include the above-described organic polymer material.

The first via insulation layer VIA1 may cover the contact electrodes CNT1, CNT2, CNT3, and CNT4 and the bottom contact BC on the display area DA, and may cover the first pad PAD1 on the pad area PDA.

Thereafter, the first via holes VH1 may be formed by partially etching the first via insulation layer VIA1. Through each of the first via holes VH1, the upper surface of the contact electrode CNT may be exposed. Through the etching process of the first via insulation layer VIA1, the second pad hole PH2, which exposes the upper surface of the first pad PAD1, may be formed on the pad area PDA.

Referring to FIG. 13, the second conductive layer, which fills the first via holes VH1 and the first pad hole PH1, may be formed on the first via insulation layer VIA1. The second conductive layer may be formed through an application or deposition process such as a sputtering process or a PVD process, and the second conductive layer may include the metal or alloy, which are described above.

Thereafter, the portion of the second conductive layer, which is formed on the upper surface of the first via insulation layer VIA1, may be partially removed through a photolithography etching process, so that the first via electrodes VE1 and the second pad PAD2 may be formed.

The first via electrodes VE1 may include the first contact portions CP1, which fills the first via holes VH1, and the first wiring portions WP1, which are formed on the upper surface of the first via insulation layer VIA1. The second pad PAD2 may be formed on the upper surface of the first via insulation layer VIA1, may fill the second pad hole PH2, and may contact and/or be connected to the upper surface of the first pad PAD1.

Referring to FIG. 14, the second via insulation layer VIA2, which covers the first via electrodes VE1, may be formed on the first via insulation layer VIA1 of the display area DA. The second via insulation layer VIA2 may be formed through a coating process such as a spin-coating process, and the second via insulation layer VIA2 may include the organic polymer material which is described above.

Thereafter, the second via holes VH2, which exposes the upper surface (e.g., the first wiring portions WP1) of the first via electrodes VE1, may be formed by partially etching the second via insulation layer VIA2.

Referring to FIG. 15, the third conductive layer CL3 may be formed on the second via insulation layer VIA2. The third conductive layer CL3 may be formed through an application or deposition process such as a sputtering process or a PVD process, and the third conductive layer CL3 may include the metal or alloy which are described above.

The third conductive layer CL3 may sufficiently fill the second via holes VH2 and may be formed on the upper surface of the second via insulation layer VIA2. The third conductive layer CL3 may be formed continuously and commonly on the display area DA and the pad area PDA.

Referring to FIG. 16, on the display area DA, the second via electrodes VE2 may be formed by partially etching the portion of the third conductive layer CL3 which is formed on the upper surface of the second via insulation layer VIA2. The second via electrodes VE2 may include the second wiring portion WP2, which is formed on the upper surface of the second via insulation layer VIA2, and the second contact portion CP2, which contacts and/or is connected to the first wiring portion WP1 within the second via insulation layer VIA2.

According to one or more embodiments, through the etching process, which is described above, of the third conductive layer CL3, the third conductive layer CL3 may be substantially removed from the pad area PDA. In one or more embodiments, the upper portion of the second pad PAD2 may also be partially etched by the etching of the third conductive layer CL3 on the pad area PDA, so that the thickness of the second pad PAD2 may be decreased.

According to one or more embodiments, the etching of the third conductive layer CL3 may include a dry etching, and the upper portion of the second pad PAD2 may be partially etched by the dry etching.

Referring to FIG. 17, the third via insulation layer VIA3, which covers the second via electrodes VE2, may be formed on the second via insulation layer VIA2. The third via insulation layer VIA3 may be formed through a coating process such as a spin-coating process and the third via insulation layer VIA3 may include the organic polymer material which is described above.

In one or more embodiments, the third via insulation layer VIA3 may be formed together on the display area DA and the pad area PDA.

Referring to FIG. 18, the portion of the third via insulation layer VIA3, which is formed on the pad area PDA, may be removed. According to one or more embodiments, the portion of the third via insulation layer VIA3, which is formed on the pad area PDA, may be removed through a wet etching process.

In one or more embodiments, after forming a photoresist layer, which selectively covers the portion of the third via insulation layer VIA3 formed on the display area DA, the portion of the third via insulation layer VIA3, which is formed on the pad area PDA, may be etched using the photoresist layer as an etching mask.

According to one or more embodiments, through the wet etching process of the third via insulation layer VIA3, the upper portion of the second pad PAD2 may be partially removed, so that the thickness of the second pad PAD2 may be additionally decreased.

In one or more embodiments, the thickness of the second pad PAD2 may be less than the thickness of the second wiring portion WP2 of the second via electrode VE2.

Referring to FIG. 19, the light-emitting element, which is described with reference to FIG. 2, may be formed on the portion of the third via insulation layer VIA3 in the display area DA.

According to one or more embodiments, the via hole, which exposes the upper surface of the second wiring portion WP2 of at least one of the second via electrodes VE2, may be formed by partially etching the third via insulation layer VIA3. Thereafter, the pixel electrode layer, which fills the via hole, may be formed on the third via insulation layer VIA3, and the pixel electrode PE (e.g., a plurality of pixel electrodes PE, e.g., one per pixel) may be formed by patterning the pixel electrode layer.

In one or more embodiments, the formation of the via hole and the removal of the third via insulation layer VIA3 on the pad area PDA, which is described with reference to FIG. 18, may be performed together through the same process.

The pixel-defining layer PDL, which covers the peripheral portion of the pixel electrode PE, may be formed on the upper surface of the third via insulation layer VIA3. In one or more embodiments, the pixel-defining layer PDL may be formed by coating a photosensitive organic material such as a polysiloxane resin, a polyimide resin, an acrylic resin, and/or the like, and performing an exposure and development process. In one or more embodiments, the pixel-defining layer PDL may also be formed through a printing process such as an inkjet printing process using a polymer material or an inorganic material.

The emission portion EL may be formed on the upper surface of the pixel electrode PE, which is exposed by the pixel-defining layer PDL, and on the sidewall of the pixel-defining layer PDL.

The emission portion EL may be formed through an application process such as thermal deposition, evaporation deposition, vacuum deposition, spin coating, inkjet printing, laser printing, casting, laser thermal transfer, and/or the like, and the emission portion EL may include the organic light-emitting material which is described above.

As described above, the emission portion EL may include the hole transport layer, the emission layer, and the electron transport layer.

In one or more embodiments, the hole transport layer and the electron transport layer may be formed continuously and commonly across the plurality of pixels or pixel electrodes PE and the pixel-defining layer PDL. In one or more embodiments, the emission layer may be selectively patterned for each pixel electrode PE of a corresponding pixel.

After forming the counter electrode CE, which is provided as the common electrode on the pixel-defining layer PDL and the emission portion EL, the encapsulation layer, which protects the pixels and the counter electrode CE, may be formed. The encapsulation layer may be formed so that the encapsulation layer may include the multi-layer structure of the inorganic insulation layer and the organic insulation layer. For example, the encapsulation layer may be formed as a sequentially stacked structure of the first inorganic insulation layer, the organic insulation layer, and the second inorganic insulation layer.

According to one or more embodiments of the present disclosure, the formation of the first pad electrode PAD1 and the second pad electrode PAD2 and the partial etching of the second pad electrode PAD2 may be performed using the formation or patterning process of the via electrode and the via insulation layer.

Accordingly, the pad 190, which has the appropriate or suitable number of stacked layers, may be formed and the damage of the bottom pad BPD may be prevented or reduced.

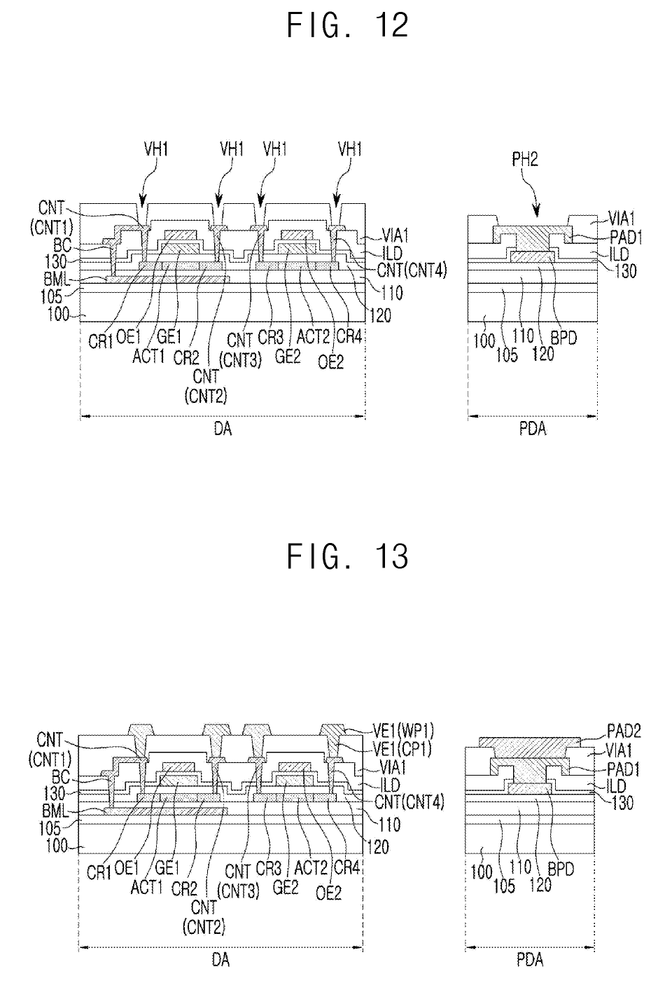

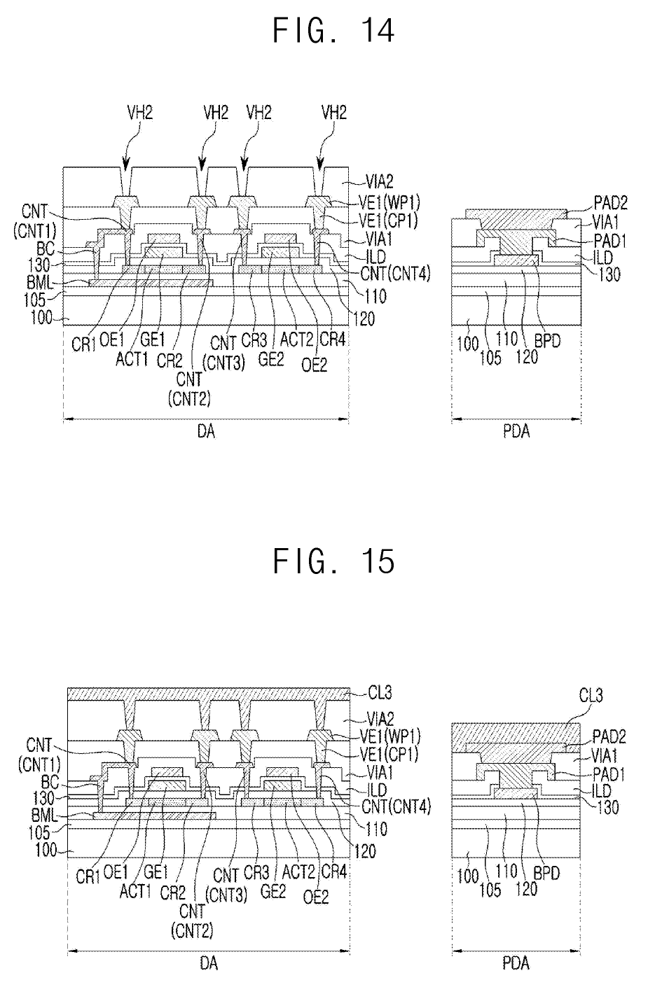

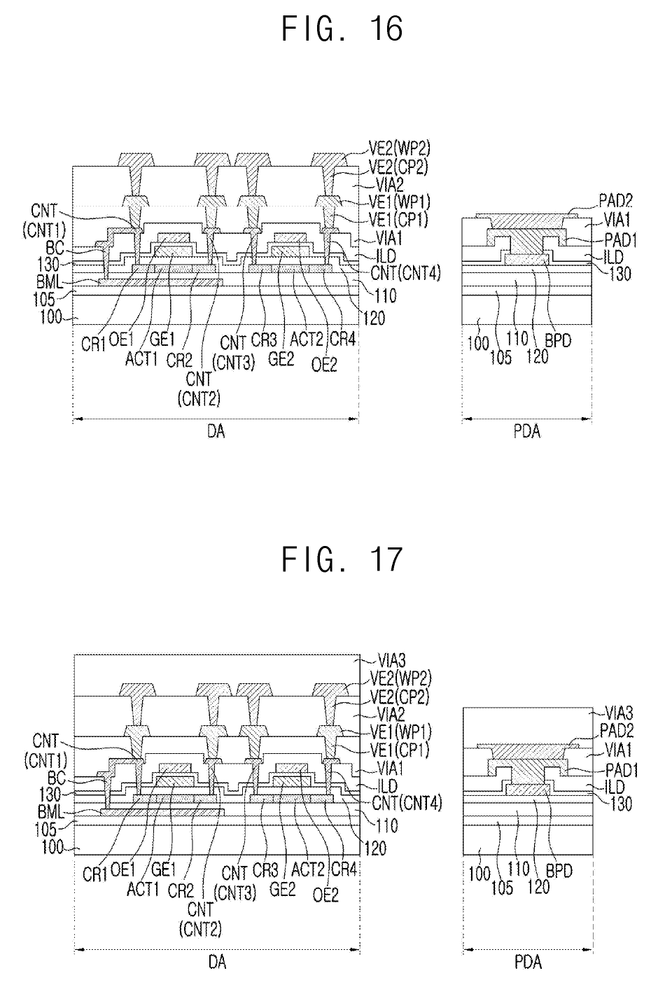

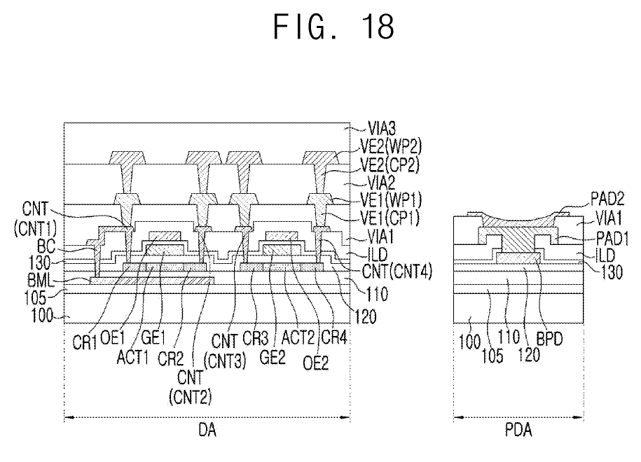

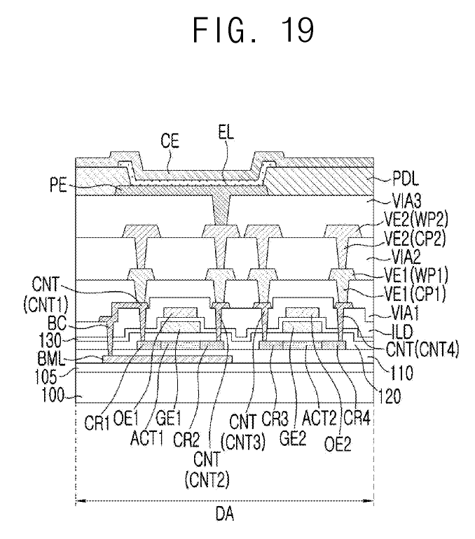

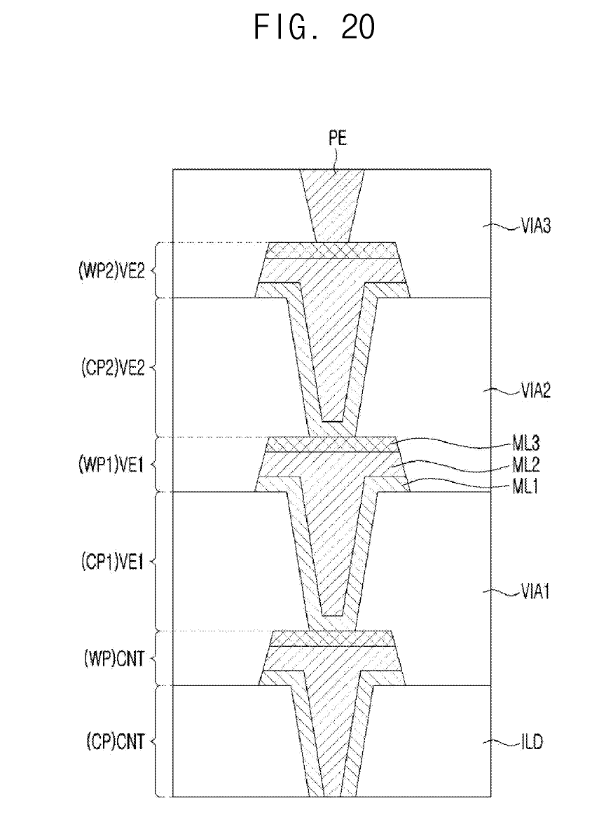

FIG. 20 is an enlarged partial cross-sectional view illustrating a stacked structure of a contact electrode and a via electrode of the display device according to one or more embodiments of the present disclosure.

Referring to FIG. 20, as described with reference to FIG. 2, a multi-layer structure of the contact electrodes CNT, the first via electrodes VE1, and the second via electrodes VE2 may be formed on (in) the display area DA. The contact electrodes CNT, like the first and the second via electrodes VE1, VE2, may each have a wiring portion WP and a contact portion CP.

In one or more embodiments, each of the contact electrodes CNT, the first via electrodes VE1, and the second via electrodes VE2 may have the multi-layer structure. In one or more embodiments, each of the contact electrodes CNT, the first via electrodes VE1, and the second via electrodes VE2 may have the multi-layer structure of the first metal layer ML1, the second metal layer ML2, and the third metal layer ML3.

The second metal layer ML2 may include a metal which has lower resistant than a metal included in the first metal layer ML1 and third metal layer ML3. For example, the second metal layer ML2 may include Al or Ag. In one or more embodiments, the second metal layer ML2 may include Al.

Each of the first metal layer ML1 and third metal layer ML3 may include a metal which is more chemically stable than the metal included in the second metal layer ML2. For example, each of the first metal layer ML1 and third metal layer ML3 may include Ti or Ta. In one or more embodiments, each of the first metal layer ML1 and third metal layer ML3 may include Ti.

In one or more embodiments, each of the contact electrodes CNT, the first via electrodes VE1, and the second via electrodes VE2 may have the sequential multi-layer structure of a Ti layer-Al layer-Ti layer.

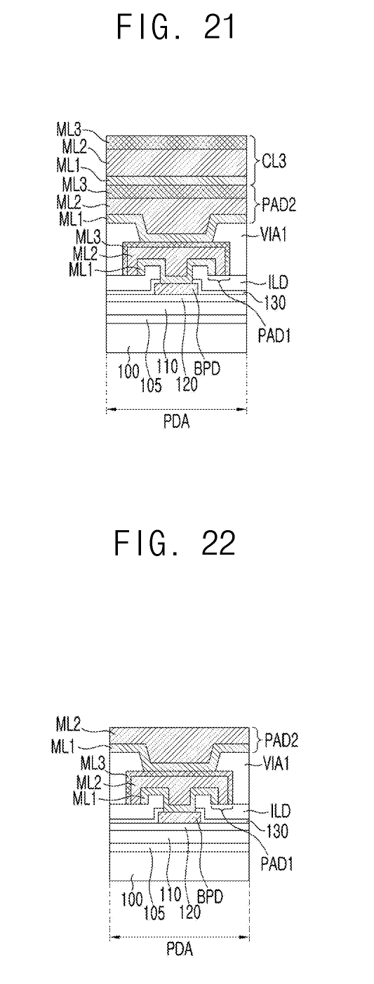

FIGS. 21 - 24 are schematic cross-sectional views explaining a method of manufacturing the display device according to one or more embodiments of the present disclosure. A detailed description of processes which are substantially the same as or similar to the processes described with reference to FIGS. 3 - 19 may not be repeated.

Referring to FIG. 21, processes, which are substantially the same as or similar to the processes described with reference to FIGS. 3 - 15, may be performed.

Accordingly, the bottom pad BPD, the first pad PAD1, the second pad PAD2, and the third conductive layer CL3 may be sequentially stacked on the pad area PDA. Each of the first pad PAD1, the second pad PAD2, and the third conductive layer CL3 may have a sequential stacked structure of the first metal layer ML1, the second metal layer ML2, and the third metal layer ML3.

Referring to FIG. 22, processes, which are substantially the same as or similar to the processes described with reference to FIG. 16, may be performed.

Accordingly, if (e.g., when) the third conductive layer CL3 is removed from the pad area PDA, the upper portion of the second pad PAD2 may be partially removed. In one or more embodiments, as described above, while the third conductive layer CL3 is removed by the dry etching, the third metal layer ML3 of the second pad PAD2, for example, which includes titanium Ti, may be removed.

Referring to FIG. 23, processes, which are substantially the same as or similar to the processes described with reference to FIG. 17, may be performed. Accordingly, the third via insulation layer VIA3 may be formed on the second pad PAD2.

Referring to FIG. 24, processes, which are substantially the same as or similar to the processes described with reference to FIG. 18, may be performed.

In one or more embodiments, while the portion of the third via insulation layer VIA3, which is formed on the pad area PDA, is removed by the wet etching, the second metal layer ML2 of the second pad PAD2, for example, which includes aluminum Al, may be removed. Accordingly, the second pad PAD2, in which substantially the first metal layer ML1 remains, may remain on the first pad PAD1.

While the first pad PAD1 maintains the stacked structure of the first metal layer ML1, the second metal layer ML2, and the third metal layer ML3, the first pad PAD1 may be included in the pad 190.

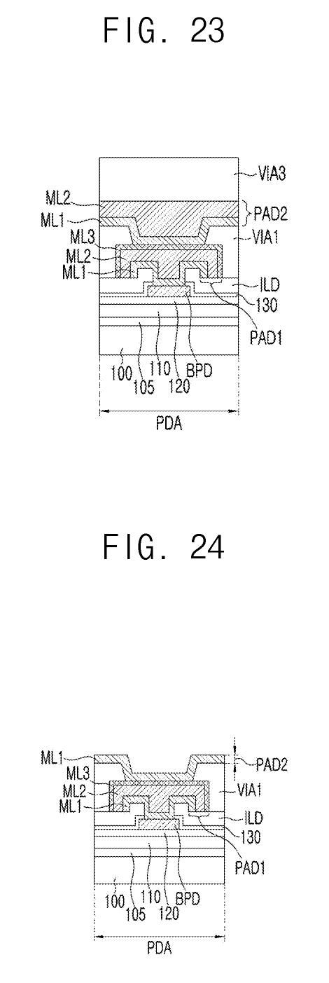

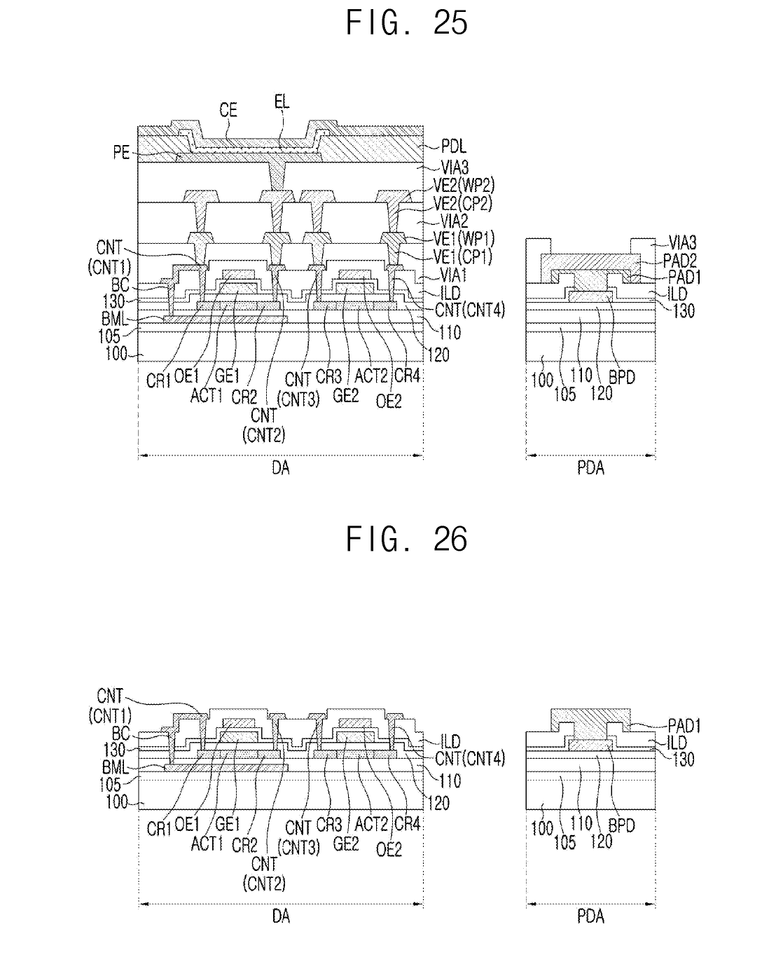

FIG. 25 is a schematic cross-sectional view illustrating the display device according to one or more embodiments of the present disclosure. The detailed description of configurations and structures which are substantially the same as or similar to those described with reference to FIG. 2 may not be repeated.

Referring to FIG. 25, the transistor structures TR1 and TR2, the via electrodes VE1 and VE2, and the light-emitting element, which are described with reference to FIG. 2, may be arranged on the display area DA.

The pad 190, which includes the bottom pad BPD, the first pad PAD1, and the second pad PAD2, may be arranged on the pad area PDA.

As described with reference to FIG. 2, the bottom pad BPD may be arranged on the first gate insulation layer 120 and may be formed of a layer of the same material as the gate electrode GE1 and GE2 (e.g., the bottom pad BPD and the gate electrodes GE1 and GE2 may be formed concurrently in the same layer). In one or more embodiments, the bottom pad BPD and the gate electrode GE1 and GE2 may have substantially the same thickness.

The second gate insulation layer 130 and the interlayer insulation layer ILD may partially cover the bottom pad BPD. The first pad PAD1 may be formed on the interlayer insulation layer ILD, may penetrate (extend through) the interlayer insulation layer ILD, and may contact and/or be connected to the upper surface of the bottom pad BPD.

The second pad PAD2 may be arranged on the interlayer insulation layer ILD and may cover the first pad PAD1. According to one or more embodiments, the second pad PAD2 may entirely cover (e.g., may cover the entirety of) the upper surface of the first pad PAD1. The second pad PAD2 may entirely cover (e.g., may cover the entirety of) the upper surface and the side surface of the first pad PAD1.

The second pad PAD2 may have a greater thickness than the first pad PAD1. According to one or more embodiments, the thickness of the second pad PAD2 may be substantially the same as the thickness of the second wiring portion WP2 of the second via electrode VE2. The thickness of the first pad PAD1 may be less than the thickness of the contact electrode CNT on the upper surface of the interlayer insulation layer ILD.

As described above, the thickness of the first pad PAD1 may be decreased, so that the cracks and the damage of the bottom pad BPD, which may be caused by the excessive increase of the number of stacked layers included in the pad 190, may be prevented or reduced. In addition, in one or more embodiments, the number of interlayer interfaces included in the pad 190 may be decreased, so that the conductivity through the pad 190 may be improved.

FIGS. 26- 32 are schematic cross-sectional views explaining a method of manufacturing the display device according to one or more embodiments of the present disclosure. A detailed description of processes which are substantially the same as or similar to the processes described with reference to FIGS. 2 - 19 may not be repeated.

Referring to FIG. 26, processes which are substantially the same as or similar to the processes described with reference to FIGS. 3 to 11 may be performed.

Accordingly, the first transistor structure TR1 (see, e.g., FIG. 2) and the second transistor structure TR2 may be formed on the base substrate of the display area DA. In addition, in one or more embodiments, the bottom contact BC which is connected to the bottom metal layer BML may be formed.

The bottom pad BPD may be formed together with the gate electrode GE1 and GE2 on the base substrate of the pad area PDA. In addition, in one or more embodiments, the first pad PAD1, which contacts or is connected to the bottom pad BPD by penetrating (extending through) the insulation layer ILD, may be formed on the insulation layer ILD.

As described above, the contact electrodes CNT and the first pad PAD1 may be formed together through the application/deposition and etching processes of the first conductive layer.

Referring to FIG. 27, the first via insulation layer VIA1, which covers the contact electrode CNT, may be formed on the display area DA. Thereafter, the first via holes VH1, which exposes the upper surfaces of the contact electrodes CNT, may be formed by partially etching the first via insulation layer VIA1.

Referring to FIG. 28, the second conductive layer CL2, which fills the via holes VH1, may be formed on the upper surface of the first via insulation layer VIA1. On the pad area PDA, the second conductive layer CL2 may be formed on the interlayer insulation layer ILD, and the second conductive layer CL2 may entirely cover (e.g., may cover the entirety of) the first pad PAD1.

Referring to FIG. 29, the first via electrodes VE1 may be formed by partially etching the second conductive layer CL2. The portion of the second conductive layer CL2 formed on the pad area PDA may be substantially entirely etched (e.g., substantially entirely removed).

According to one or more embodiments, the upper portion of the first pad PAD1 may be partially etched together with the etching of the second conductive layer CL2. Accordingly, the thickness of the first pad PAD1 may be decreased. The etching of the second conductive layer CL2 may include dry etching.

Referring to FIG. 30, the second via insulation layer VIA2, which covers the first via electrodes VE1, may be formed on the first via insulation layer VIA1. The second via insulation layer VIA2 may be etched and substantially removed on the pad area PDA.

According to one or more embodiments, the upper portion of the first pad PAD1 may be partially etched by the etching of the second via insulation layer VIA2. Accordingly, the thickness of the first pad PAD1 may be additionally decreased. The etching of the second via insulation layer VIA2 may include wet etching.

The second via holes VH2, which expose the upper surfaces of the first via electrodes VE1, may be formed by etching the portion of the second via insulation layer VIA2 formed in the display area DA.

In one or more embodiments, the etching of the second via insulation layer VIA2 on the pad area PDA may be performed together with the formation of the second via holes VH2.

Referring to FIG. 31, the third conductive layer may be formed on the upper surface of the second via insulation layer VIA2, and the second via electrodes VE2 and the second pad PAD2 may be formed by etching the third conductive layer.

The second pad PAD2 may entirely cover (e.g., may cover the entirety of) the upper surface and the side surface of the first pad PAD1. The second pad PAD2 may have the thickness which is substantially the same as that of the second wiring portions WP2 of the second via electrodes VE2.

Referring to FIG. 32, the third via insulation layer VIA3, which covers the second via electrodes VE2 and the second pad PAD2, may be formed on the second via insulation layer VIA2.

Thereafter, the third via hole VH3, which exposes the second wiring portion WP2 of at least one of the second via electrodes VE2, may be formed by partially etching the third via insulation layer VIA3. The second pad hole PH2, which exposes the upper surface of the second pad PAD2, may be formed on the pad area PDA by the etching of the third via insulation layer VIA3.

Thereafter, as described with reference to FIG. 19, the light-emitting element including the pixel electrode PE which fills the third via hole VH3 and is formed on the third via insulation layer VIA3, may be formed.

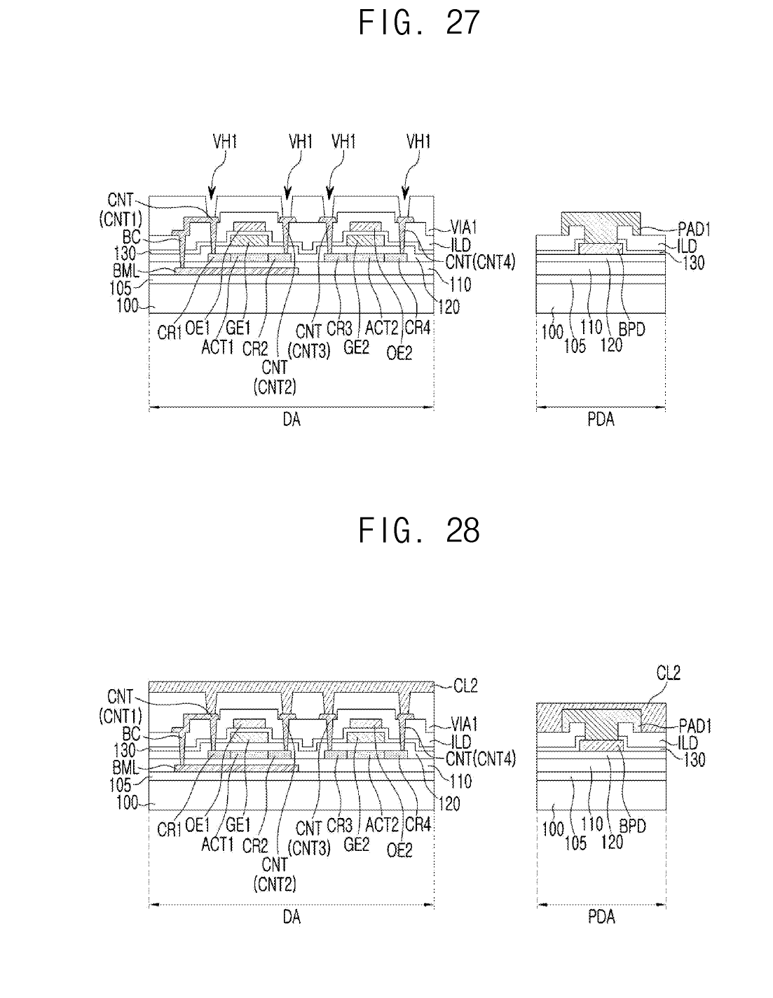

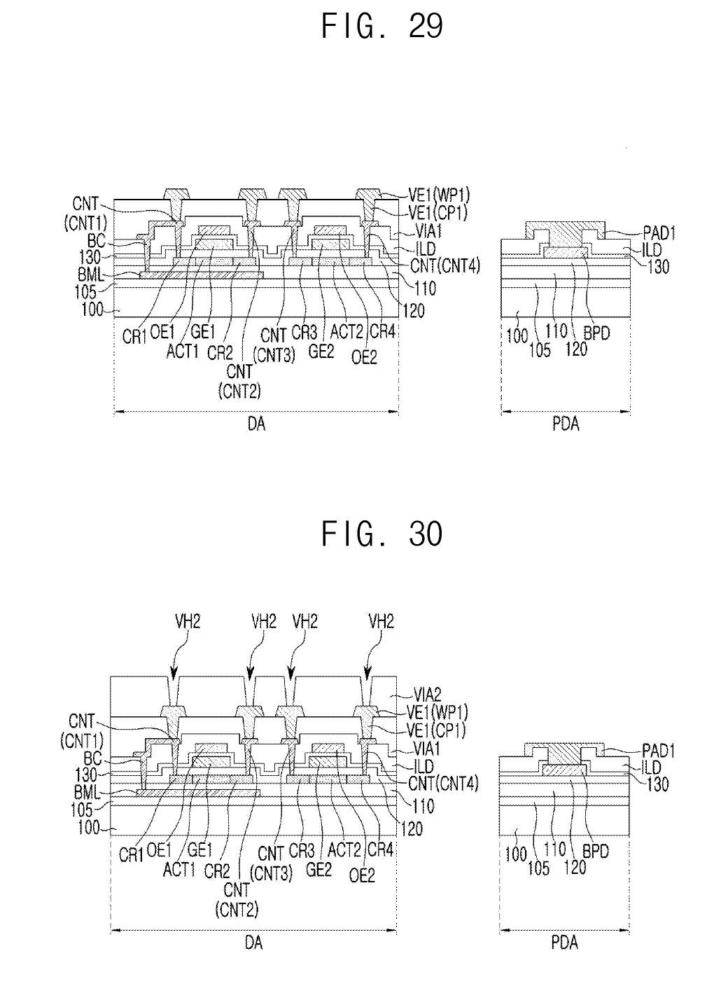

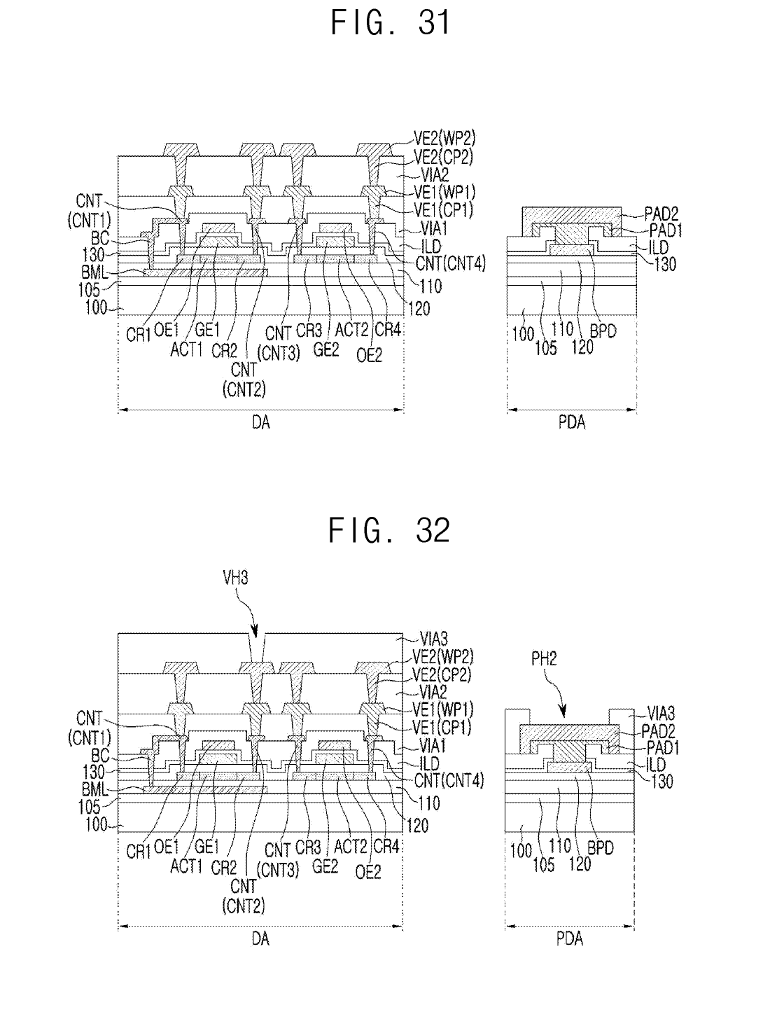

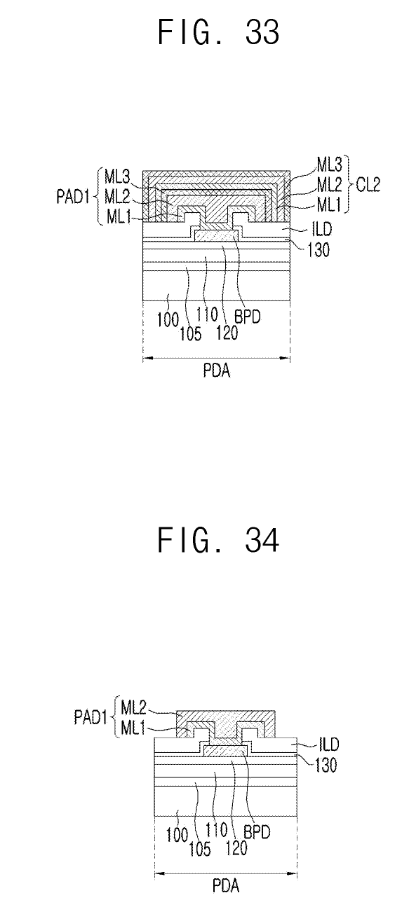

FIGS. 33 - 35 are schematic cross-sectional views explaining a method of manufacturing a display device according to one or more embodiments of the present disclosure. A detailed description of processes which are substantially the same as or similar to the processes described with reference to FIGS. 25 - 32 may not be repeated.

Referring to FIG. 33, processes which are substantially the same as or similar to the processes described with reference to FIGS. 25 - 28 may be performed.

Accordingly, the bottom pad BPD may be formed on the first gate insulation layer 120 and the first pad PAD1 and the second conductive layer CL2 may be sequentially formed on the bottom pad BPD. Each of the first pad PAD1 and the second conductive layer CL2 may have the multi-layer structure of the first metal layer ML1, the second metal layer ML2, and the third metal layer ML3.

Referring to FIG. 34, processes which are substantially the same as or similar to the process described with reference to FIG. 29 may be performed.

Accordingly, while the second conductive layer CL2 is removed on the pad area PDA, the third metal layer ML3 of the first pad PAD1, which includes, for example, Ti, may be removed together with the second conductive layer CL2.

Referring to FIG. 35, processes which are substantially the same as or similar to the processes described with reference to FIGS. 30 and 31 may be performed.

According to one or more embodiments, as described with reference to FIG. 30, on the display area DA, the second metal layer ML2 of the first pad PAD1, which includes, for example, Al, may be selectively etched or removed along with the wet etching of the second via insulation layer VIA2. Accordingly, only the first metal layer ML1 among the first pad PAD1 may substantially remain.

Thereafter, as described with reference to FIG. 31, the second pad PAD2, which has the sequential multi-layer structure of the first metal layer ML1, the second metal layer ML2, and the third metal layer ML3, may be formed on the first pad PAD1.

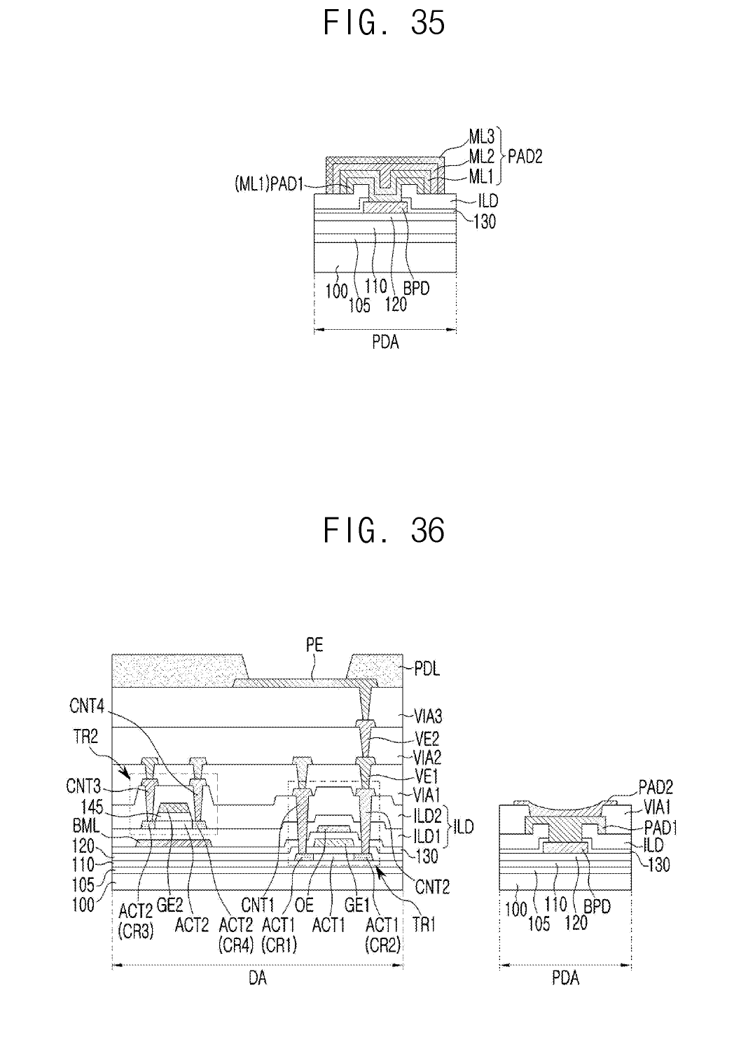

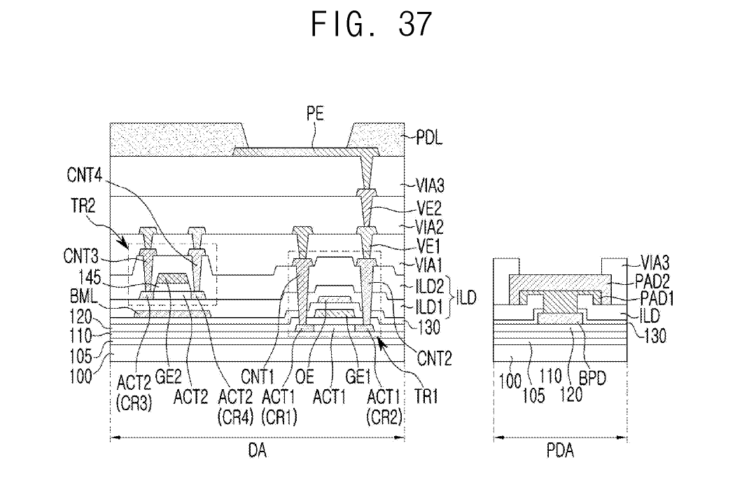

FIGS. 36 and 37 are schematic cross-sectional views illustrating the display device according to one or more embodiments of the present disclosure. According to one or more embodiments, FIGS. 36 and 37 illustrate a display device in which a transistor having an active layer, which is formed of an oxide semiconductor, and a transistor, which has a silicon-based active layer, are mixed. A detailed description of configurations and structures which are substantially the same as or similar to those described with reference to FIGS. 2 and 25 may not be repeated.

Referring to FIGS. 36 and 37, the first transistor structure TR1 and the second transistor structure TR2 may be arranged on the base substrate 100 of the display area DA.

The first transistor structure TR1 may include the first active layer ACT1 which includes the silicon-based compound which is described above, and the second transistor structure TR2 may include the second active layer ACT2 which includes the oxide semiconductor which is described above.

The second active layer ACT2 may be positioned at a level higher than the first active layer ACT1. The first active layer ACT1 may be arranged on the buffer layer 110.

According to one or more embodiments, the interlayer insulation layer ILD may include the first interlayer insulation layer ILD1 and the second interlayer insulation layer ILD2. The first interlayer insulation layer ILD1 may be formed on the second gate insulation layer 130 and may cover the overlap electrode OE and the bottom metal layer BML.

The overlap electrode OE may overlap the first gate electrode GE1 in the thickness direction with the second gate insulation layer 130 interposed. The bottom metal layer BML may be arranged below the second active layer ACT2 and may overlap the second active layer ACT2 in the thickness direction with the first interlayer insulation layer ILD1 interposed.

The second active layer ACT2 may be arranged on the upper surface of the first interlayer insulation layer ILD1. The second gate electrode GE2 may overlap the channel area of the second active layer ACT2 with the gate insulation pattern 145 interposed therebetween. The second interlayer insulation layer ILD2 may cover the second gate electrode GE2 on the first interlayer insulation layer ILD1.

Each of the first and second contact electrodes CNT1 and CNT2 may penetrate (extend through) the interlayer insulation layer ILD, the second gate insulation layer 130, and the first gate insulation layer 120, and may contact and/or be connected to the first contact area CR1 or the second contact area CR2, respectively, of the first active layer ACT1.

Each of the third and fourth contact electrodes CNT3 and CNT4 may penetrate (extend through) the second interlayer insulation layer ILD2, and may contact and/or be connected to the third contact area CR3 or the fourth contact area CR4, respectively, of the second active layer ACT2. In one or more embodiments, as described with reference to FIG. 2, the bottom contact BC, which is connected to the bottom metal layer BML and the third contact electrode CNT3, may be formed.

The stacked structures of at least one of the first via electrodes VE1 and one of the second via electrodes VE2 may be arranged on the upper surface of the second contact electrode CNT2.

As described in FIG. 36, the pad 190, which is substantially the same as or similar to the pad 190 described with reference to FIG. 2, may be arranged on the base substrate 100 of the pad area PDA. The pad 190 may include the bottom pad BPD, the first pad PAD1, and the second pad PAD2, which has a relatively decreased thickness.

As described in FIG. 37, the pad 190, which is substantially the same as or similar to the pad 190 described with reference to FIG. 25, may be arranged on the base substrate 100 of the pad area PDA. The pad 190 may include the bottom pad BPD, the first pad PAD1 which has a relatively reduced thickness, and the second pad PAD2 which surrounds the first pad PAD1.

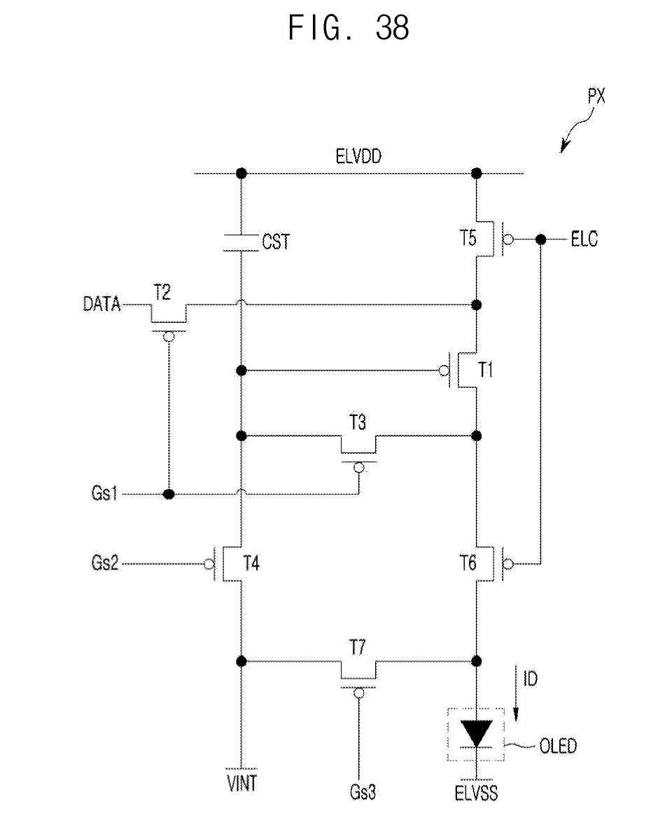

FIG. 38 is an equivalent circuit diagram of the display device according to one or more embodiments of the present disclosure.

Referring to FIG. 38, each pixel PX may include a first transistor T1, a second transistor T2, a third transistor T3, a fourth transistor T4, a fifth transistor T5, a sixth transistor T6, a seventh transistor T7, and a storage capacitor CST.

The first transistor T1 may include a gate terminal, a first terminal, and a second terminal. The gate terminal may be connected to the storage capacitor CST. The first terminal may be connected to the second transistor T2. The second terminal may be connected to the sixth transistor T6. The first transistor T1 may be to generate a driving current ID based on a voltage difference between the gate terminal and the first terminal. For example, the first transistor T1 may be referred to as a driving transistor.

The second transistor T2 may include a gate terminal, a first terminal, and a second terminal. The gate terminal of the second transistor T2 may receive a first gate signal Gs1. The second transistor T2 may be turned on or turned off in response to the first gate signal Gs1. The first terminal of the second transistor T2 may receive a data voltage DATA. The second transistor T2 may be to provide the data voltage DATA to the first terminal of the first transistor T1 in response to the first gate signal Gs1. For example, the second transistor T2 may be referred to as a switching transistor.

The third transistor T3 may include a gate terminal, a first terminal, and a second terminal. The gate terminal may receive the first gate signal Gs1. The first terminal may be connected to the gate terminal of the first transistor T1. The second terminal may be connected to the second terminal of the first transistor T1. The third transistor T3 may be to compensate for a threshold voltage of the first transistor T1. For example, the third transistor T3 may be provided as a compensation transistor.

The fourth transistor T4 may include a gate terminal, a first terminal, and a second terminal. The gate terminal may receive a second gate signal Gs2. The first terminal may be connected to the gate terminal of the first transistor T1. The second terminal may receive an initialization voltage VINT. The fourth transistor T4 may be to initialize the gate terminal of the first transistor T1.

The fifth transistor T5 may include a gate terminal, a first terminal, and a second terminal. The gate terminal may receive an emission control signal ELC. The first terminal may receive a high-power supply voltage ELVDD. The second terminal may be connected to the first transistor T1.

The sixth transistor T6 may include a gate terminal, a first terminal, and a second terminal. The gate terminal may receive the emission control signal ELC. The first terminal may be connected to the first transistor T1. The second terminal may be connected to the organic light-emitting diode OLED. The sixth transistor T6 may be to transmit the driving current ID to the organic light-emitting diode OLED in response to the emission control signal ELC.

The seventh transistor T7 may include a gate terminal, a first terminal, and a second terminal. The gate terminal may be to receive a third gate signal Gs3. The first terminal may be connected to the organic light-emitting diode OLED. The second terminal may receive the initialization voltage VINT. The seventh transistor T7 may be to initialize the organic light-emitting diode OLED.

The storage capacitor CST may include a first terminal and a second terminal. The first terminal may receive the high-power supply voltage ELVDD and the second terminal may be connected to the gate terminal of the first transistor T1.

The organic light-emitting diode OLED may include a first terminal and a second terminal. The first terminal may be connected to the sixth transistor T6. The second terminal may receive a low power supply voltage ELVSS. The organic light-emitting diode OLED may be to emit light based on the driving current ID.

In one or more embodiments, the first transistor structure TR1, which includes the first active layer ACT1 including the silicon semiconductor described with reference to FIGS. 36 - 37, may be used as the first transistor T1. In one or more embodiments, the second transistor structure TR2, which includes the second active layer ACT2 including the oxide semiconductor, may be used as the second transistor T2.

In FIG. 38, a 7T1C structure in which seven thin film transistors and one storage capacitor CST are included in each pixel PX is illustrated, but the pixel structure of the display device disclosed in the present application is not limited thereto.

For example, each pixel PX may include two or more transistors and may have structures such as 2T1C, 5T1C, 6T1C, 5T2C, 6T2C, and/or the like.

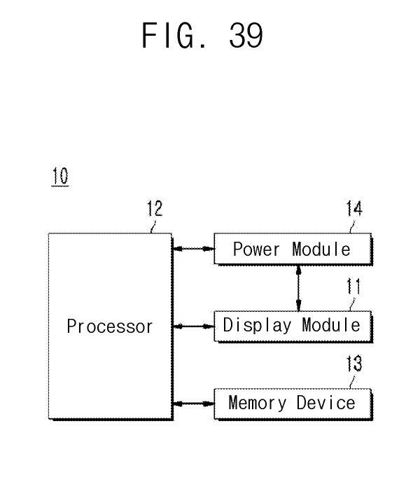

FIG. 39 is a block diagram illustrating an electronic device according to one or more embodiments of the present disclosure.

Referring to FIG. 39, an electronic device 10 according to one or more embodiments may include a display module 11, a processor 12, a memory device 13, and a power module 14.

The processor 12 may include a central processing unit (CPU), an application processor (AP), a graphic processing unit (GPU), a communication processor (CP), an image signal processor (ISP), and/or a controller.

The memory device 13 may store data information which is for operating the processor 12 or the display module 11. When the processor 12 executes an application stored in the memory 13, an image data signal and/or an input control signal may be transmitted to the display module 11, and the display module 11 may process the signal, which is received, and may output image information through a display screen.

The power module 14 may include a power supply module such as a power adapter, a battery device, and/or the like, and a power conversion module which converts power supplied by the power supply module and generates power for operating the electronic device 10.

At least one of the components of the electronic device 10 described above may be included in the display device according to one or more embodiments described above. In addition, in one or more embodiments, some among individual modules included in a functionally single module may be included in the display device, and others may be provided separately from the display device. For example, the display module 11 may include the display device, and the processor 12, the memory 13, and the power module 14 may be provided as other devices within the electronic device 10 rather than the display device.

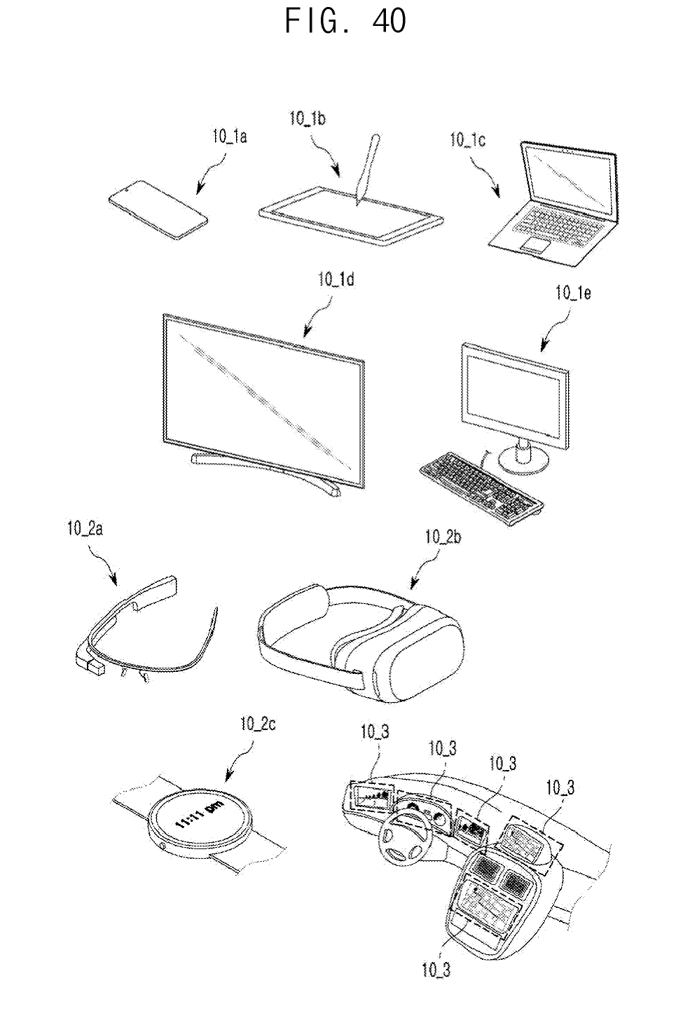

FIG. 40 shows schematic diagrams illustrating the electronic device of FIG. 39 according to various embodiments of the present disclosure.

Referring to FIG. 40, non-limiting examples of one or more suitable electronic devices to which the display device according to one or more embodiments described above may be applied, may include image display electronic devices, such as a smartphone 10_1a, a tablet PC 10_1b, a laptop 10_1c, a TV 10_1d, a desktop monitor 10_1e, and/or the like, wearable electronic devices including a display module, such as smart glasses 10_2a, a head mount display 10_2b, a smart watch 10_2c, and/or the like, and vehicle electronic devices 10_3 including a display module, such as a center information display (CID) arranged on an instrument panel, a center fascia, or a dashboard of a vehicle, a room mirror display, and/or the like. The electronic device may further include virtual reality glasses or augmented reality glasses.

The present disclosure may be applied to a display device and an electronic device including the display device. For example, the present disclosure may be applied to a television (TV), a digital TV, a 3D TV, a mobile phone, a smart phone, a tablet computer, a laptop computer, a personal computer (PC), a household electronic device, a personal digital assistant (PDA), a portable multimedia player (PMP), a digital camera, a music player, a portable game console, a navigation device, and/or the like.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ± 30%, 20%, 10%, 5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, electronic device, device for manufacturing the display device, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the claims, means-plus-function clauses are intended to cover the structures described herein as performing the recited function and not only structural equivalents but also equivalent structures.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A method comprising:
applying an active layer on a portion of a base substrate in a display area, wherein the base substrate defines the display area and a pad area;
applying a gate electrode overlapping the active layer in the display area and a bottom pad on a portion of the base substrate in the pad area;
applying a contact electrode connected to the active layer in the display area and a first pad connected to the bottom pad in the pad area;
applying a via insulation layer covering the contact electrode;
applying a via electrode connected to the contact electrode through the via insulation layer in the display area and a second pad connected to the first pad in the pad area;
partially etching an upper portion of the first pad or an upper portion of the second pad while etching the via insulation layer in the pad area; and
applying a light-emitting element electrically connected to the via electrode,
wherein the method is a method of manufacturing a display device.

2. The method of claim 1, wherein the applying of the via insulation layer comprises:
applying a first via insulation layer covering the contact electrode;
applying a second via insulation layer on the first via insulation layer; and
applying a third via insulation layer on the second via insulation layer, and
wherein the forming of the via electrode comprises:
applying a first via electrode extending through the first via insulation layer and connected to the contact electrode; and
applying a second via electrode extending through the second via insulation layer and connected to the first via electrode.

3. The method of claim 2, wherein the applying of the second via electrode comprises applying a third conductive layer on the second via insulation layer to cover the second pad in the pad area.

4. The method of claim 3, wherein the method further comprises partially etching the upper portion of the second pad while etching a portion of the third conductive layer in the pad area.

5. The method of claim 4, wherein the second pad has a sequentially stacked structure of a first metal layer, a second metal layer, and a third metal layer, and
wherein the partially etching of the upper portion of the second pad while etching the portion of the third conductive layer comprises etching the third metal layer of the second pad.

6. The method of claim 5, wherein the partially etching of the upper portion of the first pad or the second pad comprises etching the second metal layer of the second pad while etching the third via insulation layer in the pad area.

7. The method of claim 6, wherein the third metal layer of the second pad comprises titanium (Ti), and
wherein the second metal layer of the second pad comprises aluminum (Al).

8. The method of claim 2, wherein the applying of the first via electrode comprises applying a second conductive layer on the first via insulation layer to cover the first pad in the pad area.

9. The method of claim 8, wherein the method further comprises partially etching the upper portion of the first pad while etching a portion of the second conductive layer in the pad area.

10. The method of claim 9, wherein the first pad has a sequentially stacked structure of a first metal layer, a second metal layer, and a third metal layer, and
wherein the partially etching of the upper portion of the first pad while etching the portion of the second conductive layer comprises etching the third metal layer of the first pad.

11. The method of claim 10, wherein the partially etching of the upper portion of the first pad or the second pad comprises etching the second metal layer of the first pad while etching the second via insulation layer in the pad area.

12. The method of claim 11, wherein the third metal layer of the first pad comprises titanium (Ti), and
wherein the second metal layer of the first pad comprises aluminum (Al).

13. The method of claim 1, wherein the method further comprises:
applying a bottom metal layer on the portion of the base substrate in the display area before the applying of the active layer; and
applying a bottom contact connected to the bottom metal layer before the applying of the via insulation layer.

14. The method of claim 13, wherein the first pad is applied together with the bottom contact.

15. The method of claim 1, wherein the via insulation layer comprises an organic polymer material.

16. A display device comprising:
a base substrate defining a display area and a pad area;
a transistor structure on the base substrate in the display area;
a via electrode connected to the transistor structure;
a light-emitting element electrically connected to the transistor structure through the via electrode; and
a pad on the base substrate in the pad area and having a sequentially stacked structure of a bottom pad, a first pad, and a second pad,
wherein the second pad has a number of stacked layers different from a number of stacked layers of the first pad and/or has a thickness different from a thickness of the first pad, and
wherein the second pad partially contacts an upper portion of the first pad when the number of the stacked layers of the second pad is less than the number of the stacked layers of the first pad and/or the thickness of the second pad is less than the thickness of the first pad.

17. The display device of claim 16, wherein the number of the stacked layers of the second pad is greater than the number of the stacked layers of the first pad, and/or the thickness of the second pad is greater than the thickness of the first pad, and
wherein the second pad covers an entirety of the upper portion and a side surface of the first pad.

18. The display device of claim 16, wherein the via electrode comprises a contact portion and a wiring portion connected to an upper portion of the contact portion, and
wherein the number of the stacked layers or the thickness of one of the first pad or the second pad is smaller than a number of stacked layers or a thickness of the wiring portion, respectively.

19. An electronic device comprising:
a display device;
a memory device; and
a processor configured to control an operation of the display device by executing data included in the memory device,
wherein the display device comprises:
a base substrate defining a display area and a pad area;
a transistor structure on the base substrate in the display area;
a via electrode connected to the transistor structure;
a light-emitting element electrically connected to the transistor structure through the via electrode; and
a pad on the base substrate in the pad area and having a sequentially stacked structure of a bottom pad, a first pad, and a second pad,
wherein the second pad has a number of stacked layers different from a number of stacked layers of the first pad and/or has a thickness different from a thickness of the first pad, and
wherein the second pad partially contacts an upper portion of the first pad when the number of the stacked layers of the second pad is less than the number of the stacked layers of the first pad and/or the thickness of the second pad is less than the thickness of the first pad.

20. The electronic device of claim 19, wherein the electronic device is virtual reality glasses, augmented reality glasses, a smartphone, a tablet PC, a laptop, a TV, a desktop monitor, smart glasses, a head mounted display, a smart watch, or a vehicle display.
